(19) United States
(12) Patent Application Publication
(10) Pub. No.: US 2026/0250509 A1
(43) Pub. Date: Aug. 27, 2026

(54) Resin Composition, Method for Producing Cured Film, Substrate with Multilayer Film, Method for Producing Substrate with Pattern, Method for Producing Patterned Cured Film, and Method for Producing Resin Composition

(71) Applicant: Central Glass Company, Limited, Ube-shi, Yamaguchi (JP)

(72) Inventors: Takashi MASUBUCHI, Chiyoda-ku, Tokyo (JP); Takashi AOKI, Chiyoda-ku, Tokyo (JP); Fumihiro AMEMIYA, Chiyoda-ku, Tokyo (JP)

(21) Appl. No.: 18/874,654

(22) PCT Filed: Jun. 12, 2023
(86) PCT No.: PCT/JP2023/021710

§ 371 Date: Dec. 13, 2024

(30) Foreign Application Priority Data
Jun. 14, 2022 (JP) 2022-096018

(51) Int. Cl. C08L 83/04; C08G 77/06; C08J 3/05; G03F 7/004; G03F 7/039; G03F 7/075; G03F 7/11; G03F 7/20

(52) U.S. Cl. CPC C08L 83/04; C08G 77/06; C08J 3/05; G03F 7/0045; G03F 7/039; G03F 7/0757; G03F 7/11; G03F 7/2004; C08J 2383/04; G03F 7/203

(57) ABSTRACT

A resin composition includes a polymer having a constitutional unit represented by [(R²)_{d}(R³)ₑ(OR⁴)_{f}SiO_{g/2}], and a constitutional unit represented by [(R¹)_{b}MO_{c/2}], and a solvent having a 1-octanol/water partition coefficient log P_{ow} of 3 or less. In a case where a plurality of R²'s are present, R²'s are each independently an aryl group or an aralkyl group, in a case where a plurality of R³'s are present, R³'s are each independently a hydrogen atom, a linear or branched aliphatic hydrocarbon group, or an aromatic hydrocarbon group, in a case where a plurality of R⁴'s are present, R⁴'s are each independently a hydrogen atom or a linear or branched aliphatic hydrocarbon group, d is a number of 1 or more and 3 or less, e is a number of 0 or more and 2 or less, f is a number of 0 or more and less than 3, g is a number of more than 0 and 3 or less, and d+e+f+g=4. M is at least one selected from the group consisting of Fe, Co, Ni, Cu, Zn, Ga, Ge, Mo, Pd, Ag, Sn, Cs, Ba, W, and Hf, in a case where a plurality of R¹'s are present, R¹'s are each independently a hydrogen atom, a hydroxy group, a halogen group, an alkoxy group, a linear or branched aliphatic hydrocarbon group, or an aromatic hydrocarbon group, b is a number of 0 or more and less than 6, c is a number of more than 0 and 6 or less, and b+c=3 to 6.

### TECHNICAL FIELD

The present invention relates to a resin composition and an application thereof. Specifically, the present invention relates to a resin composition which is preferably applicable to a semiconductor lithography process, and various processes using the resin composition. In addition, the present invention also relates to a method for producing a resin composition.

### BACKGROUND ART

The high integration and fine patterning of LSI (Large Scale Integration) circuits are being pursued. The high integration and fine patterning of the LSI circuits have been pursued with the use of shorter-wavelength light sources in lithography and the development of resists applicable to such shorter-wavelength lithography. In LSI production, it is common to produce a substrate with a pattern by forming a resist pattern on a substrate by light exposure and development according to lithography, dry-etching the substrate with a chlorine-based gas or fluorine-based gas through the resist pattern and thereby allowing pattern transfer to the substrate. In this case, for the resist, a resin having a chemical structure resistant to etching with respect to these gases is used.

As such a resist, there are a positive resist in which an exposed portion is solubilized by irradiation with light, and a negative resist in which an exposed portion is insolubilized, and either of them is used. In this case, g-line (wavelength 463 nm), i-line (wavelength 365 nm) emitted from a high-pressure mercury lamp, ultraviolet light having a wavelength of 248 nm oscillated by a KrF excimer laser, ultraviolet light having a wavelength of 193 nm oscillated by an ArF excimer laser, or extreme ultraviolet light (hereinafter sometimes referred to as EUV), or the like is used.

On the other hand, in order to prevent the collapse of a pattern when forming the pattern of the resist and improve the etching resistance of the resist, a multilayer resist method is known.

In the case where the multilayer resist method is applied to an EUV exposure, the resist layer formed of a hydrocarbon in the related art has a low absorbance of EUV light. Therefore, for example, Patent Document 1 and Non-Patent Document 1 disclose that secondary electrons from EUV photons are returned from an underlayer film to the resist side to increase EUV photosensitivity (efficient use of EUV light) by using a material having a high EUV absorbance in the underlayer film of the resist (using an MoSi pair as a multilayer stack).

### RELATED DOCUMENT

### Patent Document

[Patent Document 1] Japanese Unexamined Patent Publication No. 2017-224819

### Non-Patent Document

[Non-Patent Document 1]2018 EUVL Workshop, Workshop Proceedings, p52

### SUMMARY OF THE INVENTION

### Technical Problem

As a method for increasing the EUV absorbance of the underlayer film of the resist, in addition to the methods described in Patent Document 1 and Non-Patent Document 1, it is considered that a polymer into which a metal element having high EUV absorbance is introduced is used.

However, according to the past knowledge and preliminary studies of the present inventors, in the synthesis of the polymer into which a metal element is introduced, precipitation may occur. In a case of using the polymer in which the precipitation has occurred, there is a concern that a homogeneous varnish (resin composition) for forming a sufficiently flat resist underlayer film may not be produced.

In addition, the polymer into which a metal element is introduced has poor solvent solubility depending on the structure thereof, and there is a concern that a homogeneous varnish (resin composition) for forming a sufficiently flat resist underlayer film may not be produced.

Therefore, the present inventors have conducted investigations with an object of providing a homogeneous resin composition including a polymer into which a metal element is introduced.

In addition, the present inventors have also conducted investigations with an object of improving the sensitivity in EUV lithography.

### Solution to Problem

The inventors of the present invention completed the invention provided below.
1.

A resin composition including:
a polymer having a constitutional unit represented by General Formula (1), and a constitutional unit represented by General Formula (1-A); and
a solvent having a 1-octanol/water partition coefficient log P_{ow} of 3 or less,

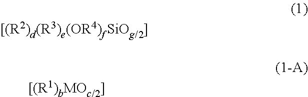

in General Formula (1),
in a case where a plurality of R²'s are present, R²'s are each independently an aryl group or an aralkyl group,
in a case where a plurality of R³'s are present, R³'s are each independently a hydrogen atom, a linear or branched aliphatic hydrocarbon group, or an aromatic hydrocarbon group,
in a case where a plurality of R⁴'s are present, R⁴'s are each independently a hydrogen atom or a linear or branched aliphatic hydrocarbon group,
d is a number of 1 or more and 3 or less, e is a number of 0 or more and 2 or less, f is a number of 0 or more and less than 3, g is a number of more than 0 and 3 or less, and d+e+f+g=4,
in General Formula (1-A),
M is at least one selected from the group consisting of Fe, Co, Ni, Cu, Zn, Ga, Ge, Mo, Pd, Ag, Sn, Cs, Ba, W, and Hf,
in a case where a plurality of R's are present, R's are each independently a hydrogen atom, a hydroxy group, a halogen group, an alkoxy group, a linear or branched aliphatic hydrocarbon group, or an aromatic hydrocarbon group,
b is a number of 0 or more and less than 6, c is a number of more than 0 and 6 or less, and b+c=3 to 6.
2.

A resin composition including:
a polysiloxane compound having a constitutional unit represented by General Formula (1);
a polymetalloxane compound having a constitutional unit represented by General Formula (1-A); and
a solvent having a 1-octanol/water partition coefficient log P_{ow} of 3 or less,

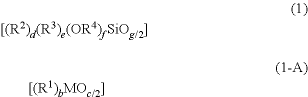

in General Formula (1),
in a case where a plurality of R²'s are present, R²'s are each independently an aryl group or an aralkyl group,
in a case where a plurality of R³'s are present, R³'s are each independently a hydrogen atom, a linear or branched aliphatic hydrocarbon group, or an aromatic hydrocarbon group,
in a case where a plurality of R⁴'s are present, R⁴'s are each independently a hydrogen atom or a linear or branched aliphatic hydrocarbon group,
d is a number of 1 or more and 3 or less, e is a number of 0 or more and 2 or less, f is a number of 0 or more and less than 3, g is a number of more than 0 and 3 or less, and d+e+f+g=4,
in General Formula (1-A),
M is at least one selected from the group consisting of Fe, Co, Ni, Cu, Zn, Ga, Ge, Mo, Pd, Ag, Sn, Cs, Ba, W, and Hf,
in a case where a plurality of R¹'s are present, R¹'s are each independently a hydrogen atom, a hydroxy group, a halogen group, an alkoxy group, a linear or branched aliphatic hydrocarbon group, or an aromatic hydrocarbon group,
b is a number of 0 or more and less than 6, c is a number of more than 0 and 6 or less, and b+c=3 to 6.
3.

The resin composition according to 1, or 2.,
in which the solvent includes at least one selected from the group consisting of glycol ethers, alcohols, esters, and ketones.
4.

The resin composition according to 1.,
in which the polymer further includes a constitutional unit represented by General Formula (2) and/or General Formula (3),

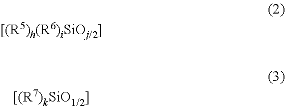

in General Formula (2),
in a case where a plurality of R⁵'s are present, R⁵'s are each independently a monovalent organic group having 1 or more and 30 or less carbon atoms and substituted with at least any substituent selected from the group consisting of an epoxy group, an oxetane group, an acryloyl group, a methacryloyl group, and a lactone group,
in a case where a plurality of R⁶'s are present, R⁶'s are each independently any group selected from the group consisting of a hydrogen atom, a halogen group, an alkyl group having 1 or more and 5 or less carbon atoms, a phenyl group, a hydroxy group, an alkoxy group having 1 or more and 3 or less carbon atoms, and a fluoroalkyl group having 1 or more and 10 or less carbon atoms,
h is a number of 1 or more and 3 or less, i is a number of 0 or more and less than 3, j is a number of more than 0 and 3 or less, and h+i+j=4,
in General Formula (3),
in a case where a plurality of R⁷'s are present, R⁷'s are each independently any group selected from the group consisting of a halogen group, an alkoxy group, and a hydroxy group,
k is a number of 0 or more and less than 4, 1 is a number of more than 0 and 4 or less, and k+1=4.
5.

The resin composition according to 4.,
in which the monovalent organic group R⁵ is any of groups represented by General Formulae (2a), (2b), (2c), (3a), and (4a),

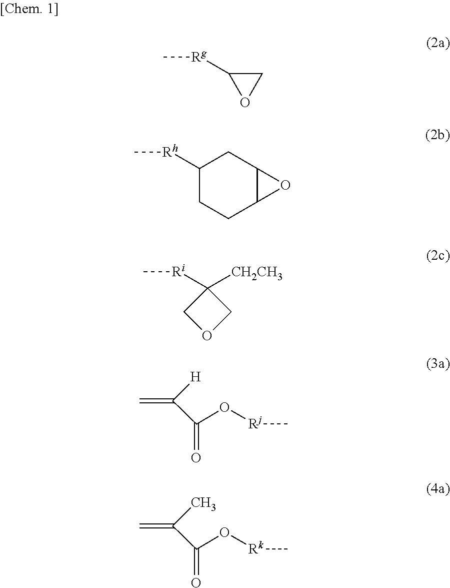

in General Formulae (2a), (2b), and (2c),
R^{g}, R^{h}, and Rⁱ each independently represent a divalent linking group, and
broken lines represent bonds,
in General Formulae (3a) and (4a),
R^{j} and R^{k} each independently represent a divalent linking group, and
broken lines represent bonds.
6.

The resin composition according to 2.,
in which at least one of the polysiloxane compound and the polymetalloxane compound further includes a constitutional unit represented by General Formula (2) and/or General Formula (3),

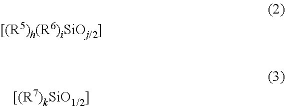

in General Formula (2),
in a case where a plurality of R⁵'s are present, R⁵'s are each independently a monovalent organic group having 1 or more and 30 or less carbon atoms and substituted with at least any substituent selected from the group consisting of an epoxy group, an oxetane group, an acryloyl group, a methacryloyl group, and a lactone group,
in a case where a plurality of R⁶'s are present, R⁶'s are each independently any group selected from the group consisting of a hydrogen atom, a halogen group, an alkyl group having 1 or more and 5 or less carbon atoms, a phenyl group, a hydroxy group, an alkoxy group having 1 or more and 3 or less carbon atoms, and a fluoroalkyl group having 1 or more and 10 or less carbon atoms,
h is a number of 1 or more and 3 or less, i is a number of 0 or more and less than 3, j is a number of more than 0 and 3 or less, and h+i+j=4,
in General Formula (3),
in a case where a plurality of R⁷'s are present, R⁷'s are each independently any group selected from the group consisting of a halogen group, an alkoxy group, and a hydroxy group,
k is a number of 0 or more and less than 4, 1 is a number of more than 0 and 4 or less, and k+1=4.
7.

The resin composition according to 6.,
in which the monovalent organic group R⁵ is any of groups represented by General Formulae (2a), (2b), (2c), (3a), and (4a),

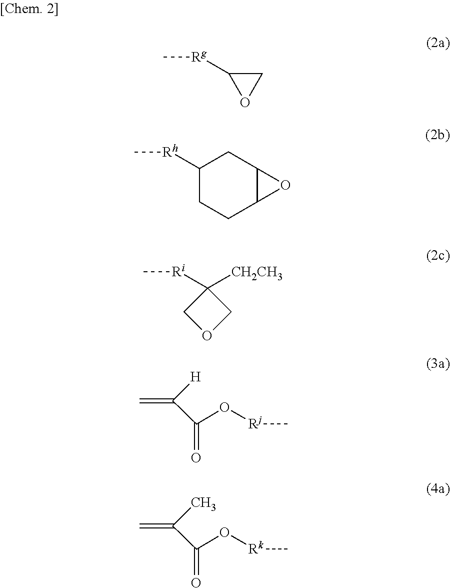

in General Formulae (2a), (2b), and (2c),
R⁹, R^{h}, and Rⁱ each independently represent a divalent linking group, and
broken lines represent bonds,
in General Formulae (3a) and (4a),
R^{j} and R^{k} each independently represent a divalent linking group, and
broken lines represent bonds.
8.

The resin composition according to 1., 3., 4., or 5.,
in which, in General Formula (1-A), M represents at least one selected from the group consisting of Ge, Mo, and W.
9.

The resin composition according to 2., 3., 6., or 7., in which in General Formula (1-A), M is at least one selected from the group consisting of Ge, Mo, and W.
10.

The resin composition according to any one of 1. to 9., in which a non-volatile component concentration is 1% to 50% by mass.
11.

The resin composition according to any one of 1. to 10.,
in which the number of particles having a particle diameter of more than 0.2 μm in particle measurement with a light scattering type liquid-borne particle detector is 100 or less per 1 mL.
12.

A method for producing a cured film, including:
a resin film forming step of applying the resin composition according to any one of 1. to 11. onto a substrate to form a resin film; and
a heating step of heating the resin film at a temperature of 80° C. or higher and 350° C. or lower.
13.

A substrate with a multilayer film, including:
a substrate;
an organic layer that is provided on one surface of the substrate;
a resist underlayer film that is a cured film of the resin composition according to any one of 1. to 3, and is provided on
a surface of the organic layer opposite to the substrate; and a resist film that is provided on a surface of the resist underlayer film opposite to the organic layer.
14.

A method for producing a substrate with a pattern, including:
a first step of exposing the resist layer of the substrate with a multilayer film according to 13. through a photomask, and then developing the exposed resist layer with a developer to obtain a pattern;
a second step of dry-etching the underlayer film through the pattern of the developed resist layer to obtain a pattern of the underlayer film;
a third step of dry-etching the organic layer through the pattern of the underlayer film to obtain a pattern of the organic layer; and
a fourth step of dry-etching the substrate through the pattern of the organic layer to obtain a pattern of the substrate.
15.

The method for producing a substrate with a pattern according to 14.,
in which, in the second step, the underlayer film is dry-etched with a fluorine-based gas,
in the third step, the organic layer is dry-etched with an oxygen-based gas, and
in the fourth step, the substrate is dry-etched with a fluorine-based gas or a chlorine-based gas.
16.

The method for producing a substrate with a pattern according to 14. or 15.,
in which a wavelength of a light beam used in the exposure is 1 nm or more and 600 nm or less.
17.

The method for producing a substrate with a pattern according to any one of 14. to 16.,
in which a wavelength of a light beam used in the exposure is 6 nm or more and 27 nm or less.
18.

The method for producing a substrate with a pattern according to any one of 14. to 17.,
in which a light beam used in the exposure is EUV light.
19.

The method for producing a substrate with a pattern according to any one of 14. to 18.,
in which the developer is an organic solvent-based developer.
20.

The resin composition according to any one of 1. to 11., further including:
a photoinduced compound,
in which the resin composition has photosensitivity.
21.

The resin composition according to 20.,
in which the photoinduced compound is at least one selected from the group consisting of naphthoquinonediazide, a photoacid generator, a photobase generator, and a photoradical generator.
22.

A method for forming a patterned cured film, including:
a photosensitive resin film forming step of applying the resin composition according to 20. or 21. onto a substrate to form a photosensitive resin film;
an exposing step of exposing the photosensitive resin film through a photomask;
a developing step of developing the exposed photosensitive resin film to form a patterned film; and
a curing step of curing the patterned film by heating the patterned film to obtain a patterned cured film.
23.

The method for producing a patterned cured film according to 22.,
in which, in the exposing step, the photosensitive resin film is irradiated with a light beam having a wavelength of 1 nm or more and 600 nm or less through the photomask.
24.

A method for producing the resin composition according to any one of 1. to 11., including:
a solution forming step of mixing a polymer obtained by conducting hydrolysis and polycondensation of a silicon compound represented by General Formula (1y) and a metal compound represented by General Formula (1-2), and the solvent having a l-octanol/water partition coefficient of 3 or less to form a solution,

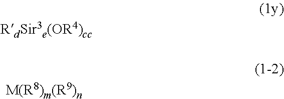

in General Formula (1y),
in a case where a plurality of R's are present, R's are each independently an aryl group or an aralkyl group,
R³ has the same definition as in General Formula (1)
R⁴ has the same definition as in General Formula (1),
d is a number of 1 or more and 3 or less, e is a number of 0 or more and 2 or less, cc is a number of 1 or more and less than 4, and d+e+cc=4,
in General Formula (1-2),
M has the same definition as in General Formula (1-A),
in a case where a plurality of R⁸'s are present, R⁸'s are each independently a hydrogen atom, a hydroxy group, a linear or branched aliphatic hydrocarbon group, or an aromatic hydrocarbon group,
in a case where a plurality of R⁹'s are present, R⁹'s are each independently an alkoxy group or halogen,
m is a number of 0 or more and 3 or less, n is a number of 1 or more and 4 or less, and m+n=3 or 4.
25.

The method for producing the resin composition according to 24.,
in which a chelating agent is used in obtaining the polymer.
26.

The method for producing the resin composition according to 24. or 25.,
in which, after the solution forming step, at least one operation selected from the group consisting of dilution with a solvent, concentration, extraction, washing with water, ion exchange resin purification, and filtration is further performed.

### Advantageous Effects of Invention

According to the present invention, a homogeneous resin composition is provided while containing a polymer into which a metal element is introduced. In addition, according to the present invention, the sensitivity in EUV lithography can be improved.

### BRIEF DESCRIPTION OF THE DRAWINGS

FIG. 1 is a view for illustrating a method for producing a substrate with a pattern and the like.

FIG. 2 is a view for illustrating a method for producing a patterned cured film and the like.

### DESCRIPTION OF EMBODIMENTS

Hereinafter, embodiments of the present invention will be described in detail with reference to the drawings.

In all the drawings, the same constitutional components are denoted by the same reference signs, and description thereof will not be repeated as appropriate.

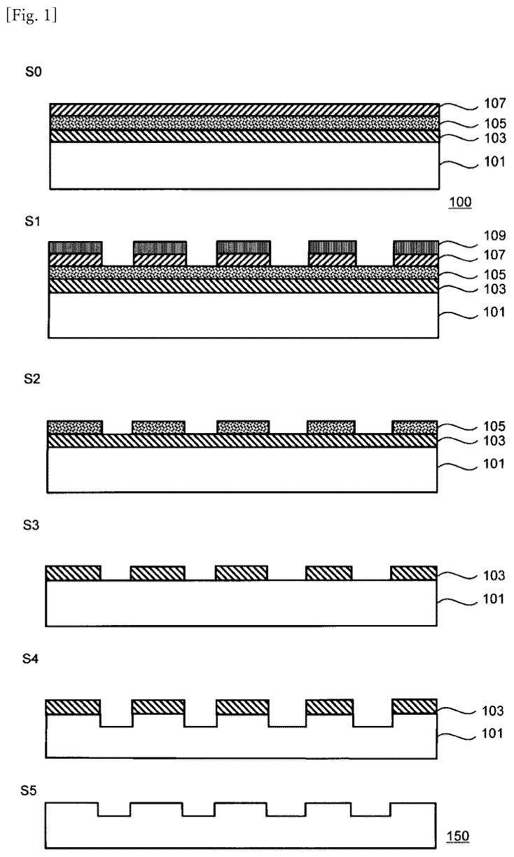

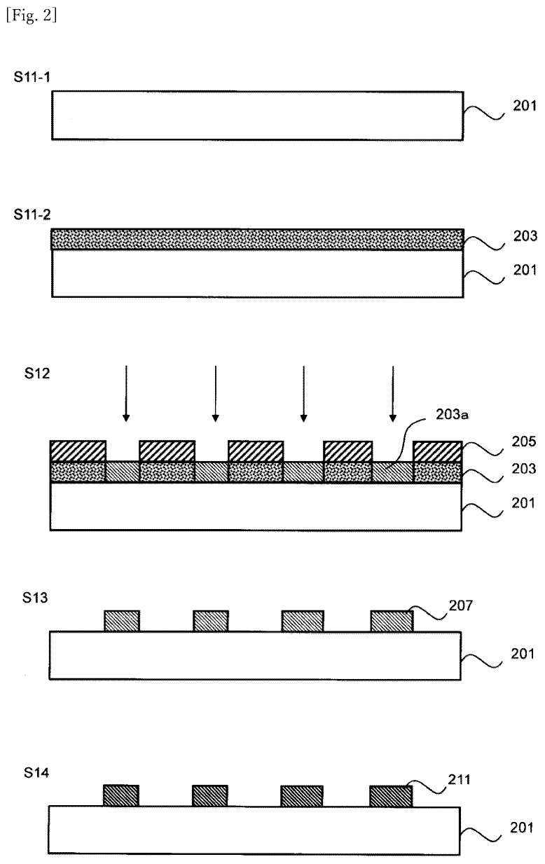

In order to avoid complication, (i) when a plurality of the same components are present in the same drawing, there may be a case where the reference numeral is given to only one component without giving the reference numeral to all the components; and (ii) in particular, in FIG. 2 and subsequent drawings, there may be a case where the reference numeral is not given again to the same components as those in FIG. 1.

All the drawings are merely illustrative. The shape or dimensional ratio of each member in the drawing does not necessarily correspond to those of an actual article.

In the present specification, the notation “X to Y” in the description of the numerical range indicates X or more and Y or less unless otherwise specified. For example, “1% to 5% by mass” means “1% by mass or more and 5% by mass or less”.

In a case where substitution or unsubstitution is not noted in regard to the notation of a group (atomic group) in the present specification, the group includes not only a group not having a substituent but also a group having a substituent. For example, the concept of an “alkyl group” includes not only an alkyl group not having a substituent (unsubstituted alkyl group) but also an alkyl group having a substituent (substituted alkyl group).

The expression “(meth)acryl” in the present specification represents a concept including both acryl and methacryl. The same applies to similar expressions such as “(meth)acrylate”.

Unless otherwise specified, the term “organic group” as used in the present specification means an atomic group obtained by removing one or more hydrogen atoms from an organic compound. For example, a “monovalent organic group” refers to an atomic group obtained by removing one hydrogen atom from any organic compound.

The term “electronic device” in the present specification is used as a meaning including an element, a device, a final product, and the like, to which electronic engineering technology has been applied, such as a semiconductor chip, a semiconductor element, a printed circuit board, an electric circuit display device, an information communication terminal, a light emitting diode, a physical battery, and a chemical battery.

### First Embodiment: Resin Composition

A resin composition according to a first embodiment includes
a polymer having a constitutional unit represented by General Formula (1) and a constitutional unit represented by General Formula (1-A), and
a solvent having a 1-octanol/water partition coefficient of 3 or less.

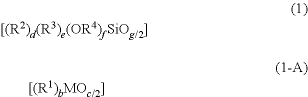

In General Formula (1),
in a case where a plurality of R²'s are present, R²'s are each independently an aryl group or an aralkyl group,
in a case where a plurality of R³'s are present, R³'s are each independently a hydrogen atom, a linear or branched aliphatic hydrocarbon group, or an aromatic hydrocarbon group,
in a case where a plurality of R⁴'s are present, R⁴'s are each independently a hydrogen atom or a linear or branched aliphatic hydrocarbon group,
d is a number of 1 or more and 3 or less, e is a number of 0 or more and 2 or less, f is a number of 0 or more and less than 3, g is a number of more than 0 and 3 or less, and d+e+f+g=4.

In General Formula (1-A),
M is at least one selected from the group consisting of Fe, Co, Ni, Cu, Zn, Ga, Ge, Mo, Pd, Ag, Sn, Cs, Ba, W, and Hf,
in a case where a plurality of R¹'s are present, R¹'s are each independently a hydrogen atom, a hydroxy group, a halogen group, an alkoxy group, a linear or branched aliphatic hydrocarbon group, or an aromatic hydrocarbon group,
b is a number of 0 or more and less than 6, c is a number of more than 0 and 6 or less, and b+c=3 to 6.

As described above, by using the specific polymer and the specific solvent in combination, a homogeneous resin composition can be produced. The reason for this is presumed as follows.
(i) Since the above polymer contains a metal element M, there is a possibility that the polymer may have low solvent solubility compared to ordinary polysiloxane. However, it is presumed that the solvent solubility is improved by including an aryl group or an aralkyl group, which is considered to have affinity with an organic solvent, as R².
(ii) It is presumed that the solvent having a 1-octanol/water partition coefficient of 3 or less has high affinity with a copolymer of siloxane and metalloxane as described above.

Hereinafter, the resin composition according to the first embodiment will be continuously described.

### (General Formula (1))

As theoretical values of d, e, f, and g, d is an integer of 1 to 3, e is an integer of 0 to 2, f is an integer of 0 to 3, and g is an integer of 0 to 3. In addition, d+e+f+g=4 means that the sum of the theoretical values is 4. However, for example, in the value obtained by ²⁹Si NMR measurement, d may be a decimal that would be 1 or more and 3 or less when rounded, e may be a decimal that would be 0 or more and 2 or less when rounded, f may be a decimal that would be 0 or more and 2 or less when rounded (where f<3.0), and g may be a decimal that would be 0 or more and 3 or less when rounded (where g≠0).

In addition, O_{g/2} is generally used as a representation of a compound having a siloxane bond. Formula (1-1) represents a case where g is 1, Formula (1-2) represents a case where g is 2, and Formula (1-3) represents a case where g is 3. In the case where g is 1, the constitutional unit is positioned at the end of the siloxane chain in the compound having the siloxane bond.

In General Formulae (1-1) to (1-3), R^{x} has the same meaning as R² in General Formula (1), and R^{a} and R^{b} each independently have the same meaning as R², R³, and OR⁴ in General Formula (1). The broken lines represent bonds with other Si atoms.

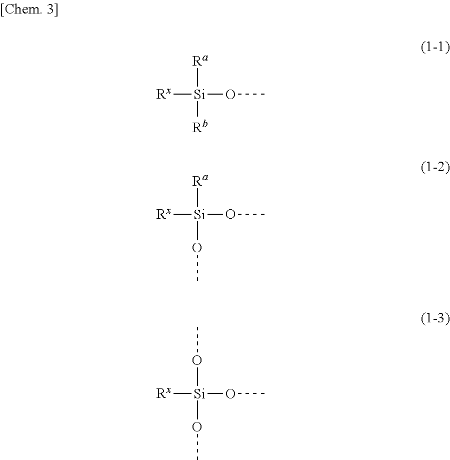

Examples of the aryl group of R² include a phenyl group, a 1-naphthyl group, a 2-naphthyl group, an anthracenyl group, and a phenanthrenyl group. The number of carbon atoms in the aryl group is preferably 6 to 20. From the viewpoint of ease of synthesis and availability of raw materials, the aryl group of R² is preferably a phenyl group.

Examples of the aralkyl group of R² in General Formula (1) include alkyl groups mentioned as examples of R³ and R⁴ described later substituted with the above-mentioned aryl groups. The number of carbon atoms in the aralkyl group is preferably 7 to 21.

Examples of the linear or branched aliphatic hydrocarbon group of R³ and R⁴ include an alkyl group. Examples of the alkyl group include a methyl group, an ethyl group, an n-propyl group, an isopropyl group, a butyl group, an isobutyl group, a tert-butyl group, an n-pentyl group, an isopentyl group, and a neopentyl group. Among these, a methyl group or an ethyl group is preferable. The number of carbon atoms in the alkyl group is preferably 1 to 5.

A part or all of hydrogen atoms of R³ in General Formula (1) may be substituted with fluorine atoms. Specifically, R³ may be a fluoroalkyl group or the like. Examples of the fluoroalkyl group include groups in which a part or all of hydrogen atoms in the alkyl group are substituted with fluorine atoms. The number of carbon atoms in the fluoroalkyl group is preferably 1 to 10.

Examples of the aromatic hydrocarbon group of R³ include an aryl group and an aralkyl group. R³ is preferably an aryl group and more preferably a phenyl group. The number of carbon atoms in the aryl group is preferably 6 to 20.

Each group of R² to R⁴ may further have or may not have a substituent. Examples of the substituent include an alkyl group, an alicyclic group, an aryl group, and a halogen atom such as a fluorine atom. Of course, substituents other than these may be used. In addition, the substituent may be an alkali-soluble group.

A part or all of hydrogen atoms included in R² may be substituted with a fluorine atom. For example, R² may be a pentafluorophenyl group.

In a case where R², R³, and R⁴ in General Formula (1) are carbon-containing groups, the total number of carbon atoms in each atomic group is, for example, 1 to 20, preferably 1 to 16, and more preferably 1 to 12.

### (General Formula (1-A))

In General Formula (1-A), as theoretical values of b and c, b is an integer of 0 to 6 and c is an integer of 0 to 6. In addition, b+c=3 to 6 means that the sum of the theoretical values is 3 to 6. However, for example, in the value obtained by polynuclear NMR measurement, each of b and c is obtained as an average value. Therefore, b as the average value may be a decimal that would be 0 or more and 6 or less when rounded (where b<6.0), and c as the average value may be a decimal that would be 0 or more and 6 or less when rounded (where c≠0). Incidentally, the theoretical value c=0 indicates that the constitutional unit is a monomer, and the average value c≠0 indicates that all of the compounds are not monomers.

Specific examples of R¹ can include the groups mentioned as the examples of R² to R⁴ in General Formula (1).

Specific examples of the alkoxy group of R¹ include a group represented by —O—R^{1′}. Here, R^{1′} can be the alkyl group mentioned as specific the example of R² to R⁴ in General Formula (1). The alkoxy group preferably has 1 to 5 carbon atoms.

Examples of the linear or branched aliphatic hydrocarbon group of R¹ include an alkyl group. Examples of the alkyl group include a methyl group, an ethyl group, an n-propyl group, an isopropyl group, a butyl group, an isobutyl group, a tert-butyl group, an n-pentyl group, an isopentyl group, and a neopentyl group. Among these, a methyl group or an ethyl group is preferable. The number of carbon atoms in the alkyl group is preferably 1 to 5. A part or all of hydrogen atoms in the linear or branched aliphatic hydrocarbon group may be substituted with fluorine atoms.

A part or all of hydrogen atoms included in R¹ may be substituted with fluorine atoms. Specifically, R¹ may be a fluoroalkyl group or the like. Examples of the fluoroalkyl group include groups in which a part or all of hydrogen atoms in the alkyl group are substituted with fluorine atoms. The number of carbon atoms in the fluoroalkyl group is preferably 1 to 10.

Examples of the aromatic hydrocarbon group of R¹ include an aryl group and an aralkyl group. R¹ is preferably an aryl group and more preferably a phenyl group. The number of carbon atoms in the aryl group is preferably 6 to 20.

M is preferably at least one selected from the group consisting of Ge, Mo, and W. M is particularly preferably Ge. Ge, Mo, and W have an aspect that the elements are easily removed by a fluorine-based etching gas. That is, it is considered that by using Ge, Mo, or W as the sensitizing element, a part of the upper layer film, which is unintentionally left on a substrate in a method for forming a pattern described later, is easily removed by the subsequent etching.

(Constitutional Unit which May be Further Included)

The polymer preferably further includes a constitutional unit represented by General Formula (2) and/or General Formula (3).

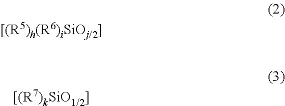

In General Formula (2),
in a case where a plurality of R⁵'s are present, R⁵'s are each independently a monovalent organic group having 1 or more and 30 or less carbon atoms and substituted with at least any substituent selected from the group consisting of an epoxy group, an oxetane group, an acryloyl group, a methacryloyl group, and a lactone group,
in a case where a plurality of R⁶'s are present, R⁶'s are each independently a group selected from the group consisting of a hydrogen atom, a halogen group, an alkyl group having 1 or more and 5 or less carbon atoms, a phenyl group, a hydroxy group, an alkoxy group having 1 or more and 3 or less carbon atoms, and a fluoroalkyl group having 1 or more and 10 or less carbon atoms,
h is a number of 1 or more and 3 or less, i is a number of 0 or more and less than 3, j is a number of more than 0 and 3 or less, and h+i+j=4.

In General Formula (3),
in a case where a plurality of R⁷'s are present, R⁷'s are each independently any group selected from the group consisting of a halogen group, an alkoxy group, and a hydroxy group,
k is a number of 0 or more and less than 4, 1 is a number of more than 0 and 4 or less, and k+1=4.

In General Formula (2), as theoretical values of h, i, and j, h is an integer of 1 to 3, i is an integer of 0 to 3, and j is an integer of 0 to 3. In addition, h+i+j=4 means that the sum of the theoretical values is 4.

However, for example, in the ²⁹Si NMR measurement, each value of h, i, and j is obtained as an average value. Therefore, h as the average value may be a decimal that would be 1 or more and 3 or less when rounded, i may be a decimal that would be 0 or more and 3 or less when rounded (where i<3.0), and j may be a decimal that would be 0 or more and 3 or less when rounded (where j≠0).

h is preferably a number of 1 or more and 2 or less, and more preferably 1. i is preferably a number of 0 or more and 2 or less, and more preferably a number of 0 or more and 1 or less. j is preferably a number of 1 or more and 3 or less, and more preferably a number of 2 or more and 3 or less.

In General Formula (3), as theoretical values of k and 1, k is an integer of 0 to 4, and l is an integer of 0 to 4. In addition, k+l=4 means that the sum of the theoretical values is 4.

However, for example, in the ²⁹Si NMR measurement, each value of k and l is obtained as an average value. Therefore, k as the average value may be a decimal that would be 0 or more and 4 or less when rounded (where k<4.0), and l may be a decimal that would be 0 or more and 4 or less when rounded (where l≠0).

k is preferably a number of 0 or more and 3 or less. l is preferably a number of 1 or more and 4 or less.

For O_{j/2} in General Formula (2), General Formula (2-1) represents a case where j is 1, General Formula (2-2) represents a case where j is 2, and General Formula (2-3) represents a case where j is 3. In a case where j is 1, the constitutional unit is positioned at the end of the siloxane chain in the compound having the siloxane bond.

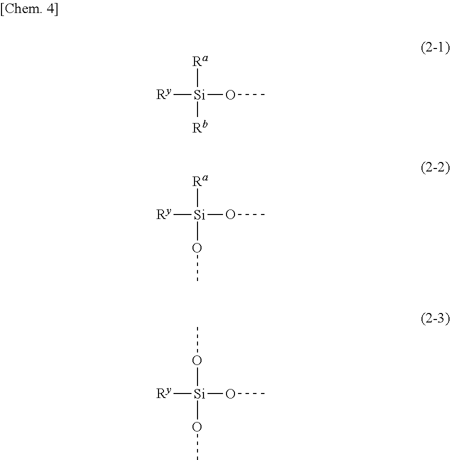

In General Formulae (2-1) to (2-3),
R^{y} has the same meaning as R⁵ in General Formula (2),
R^{a} and R^{b} each independently have the same meaning as R⁵ and R⁶ in General Formula (2), and
the broken lines represent bonds with other Si atoms.

In General Formula (3), O_{1/2} in a case of 1=4 represents General Formula (3-1). In General Formula (3-1), the broken lines represent bonds with other Si atoms.

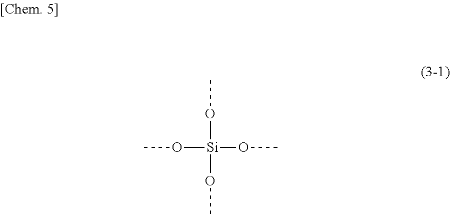

O_{4/2} in General Formula (3) is generally called a Q4 unit, and shows a structure in which all four bonds of a Si atom form siloxane bonds. Although Q4 has been described above, General Formula (3) may contain a hydrolyzable and condensable group in the bond as in Q0, Q1, Q2, and Q3 units shown below. In addition, Formula (3) may have at least one selected from the group consisting of Q1 to Q4 units, and may further include a Q0 unit.

Q0 unit: a structure in which all four bonds of a Si atom are hydrolyzable and polycondensable groups (such as a halogen group, alkoxy group, or hydroxy group that can form siloxane bonds).

Q1 unit: a structure in which one of the four bonds of a Si atom forms a siloxane bond and the other three are all hydrolyzable and polycondensable groups.

Q2 unit: a structure in which two of the four bonds of a Si atom form a siloxane bond and the other two are all hydrolyzable and polycondensable groups.

Q3 unit: a structure in which three of the four bonds of a Si atom form a siloxane bond and the other one is the hydrolyzable and polycondensable group.

Preferable examples of a monomer (raw material) corresponding to the constitutional unit represented by General Formula (3) include tetraalkoxysilane, tetrahalosilane (for example, tetrachlorosilane, tetramethoxysilane, tetraethoxysilane, tetra-n-propoxysilane, tetraisopropoxysilane, or the like), and an oligomer of these compounds.

Due to the presence of the monovalent organic group R⁵, the resin composition according to the first embodiment may be thermosetting or photocurable.

The monovalent organic group R⁵ is preferably any of groups represented by General Formulae (2a), (2b), (2c), (3a), and (4a).

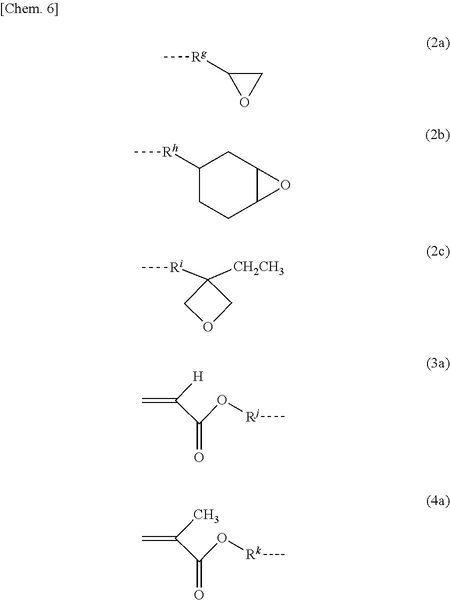

In General Formulae (2a), (2b), and (2c),
R⁹, R^{h}, and Rⁱ each independently represent a divalent linking group, and
the broken lines represent bonds.

In General Formulae (3a) and (4a),
R^{j} and R^{k} each independently represent a divalent linking group, and
the broken lines represent bonds.

In a case where R⁹, R^{h}, and Rⁱ each are a divalent linking group, specific examples thereof, for example, include an alkylene group having for 1 to 20 carbon atoms. The alkylene group may contain one or more moieties in which an ether bond is formed. In a case where the number of carbon atoms is 3 or more, the alkylene group may be branched, or carbons spaced apart from each other may be connected to each other to form a ring. In a case where the number of carbon atoms of the alkylene group is 2 or more, one or more moieties in which an ether bond is formed by inserting oxygen between carbons may be contained.

In a case where Rⱼ and Rₖ each are a divalent linking group, preferable examples thereof include again those exemplified above as the preferred groups in R^{g}, R^{h}, and Rⁱ.

Examples of the alkoxysilane as a raw material for the particularly preferable one among the second constitutional units represented by General Formula (2) include the following: 3-glycidoxypropyltrimethoxysilane (manufactured by Shin-Etsu Chemical Co., Ltd., product name: KBM-403), 3-glycidoxypropyltriethoxysilane (manufactured by Shin-Etsu Chemical Co., Ltd., product name: KBE-403), 3-glycidoxypropylmethyldiethoxysilane (manufactured by Shin-Etsu Chemical Co., Ltd., product name: KBE-402), 3-glycidoxypropylmethyldimethoxysilane (manufactured by Shin-Etsu Chemical Co., Ltd., product name: KBM-402), 2-(3,4-epoxycyclohexyl)ethyltrimethoxysilane (manufactured by Shin-Etsu Chemical Co., Ltd., product name: KBM-303), 2-(3,4-epoxycyclohexyl)ethyltriethoxysilane, 8-glycidoxyoctyltrimethoxysilane (manufactured by Shin-Etsu Chemical Co., Ltd., product name: KBM-4803), [(3-ethyl-3-oxetanyl)methoxy]propyltrimethoxysilane, and [(3-ethyl-3-oxetanyl)methoxy]propyltriethoxysilane.

In addition, specific examples thereof also include 3-methacryloxypropyltrimethoxysilane (manufactured by Shin-Etsu Chemical Co., Ltd., product name: KBM-503), 3-methacryloxypropyltriethoxysilane (manufactured by Shin-Etsu Chemical Co., Ltd., product name: KBE-503), 3-methacryloxypropylmethyldimethoxysilane (manufactured by Shin-Etsu Chemical Co., Ltd., product name: KBM-502), 3-methacryloxypropylmethyldiethoxysilane (manufactured by Shin-Etsu Chemical Co., Ltd., product name: KBE-502), 3-acryloxypropyltrimethoxysilane (manufactured by Shin-Etsu Chemical Co., Ltd., product name: KBM-5103), and 8-methacryloxyoctyltrimethoxysilane (manufactured by Shin-Etsu Chemical Co., Ltd., product name: KBM-5803).

In a case where R⁵ includes a lactone group, when the R⁵ is represented by a R⁵—Si structure, specific examples are as below.

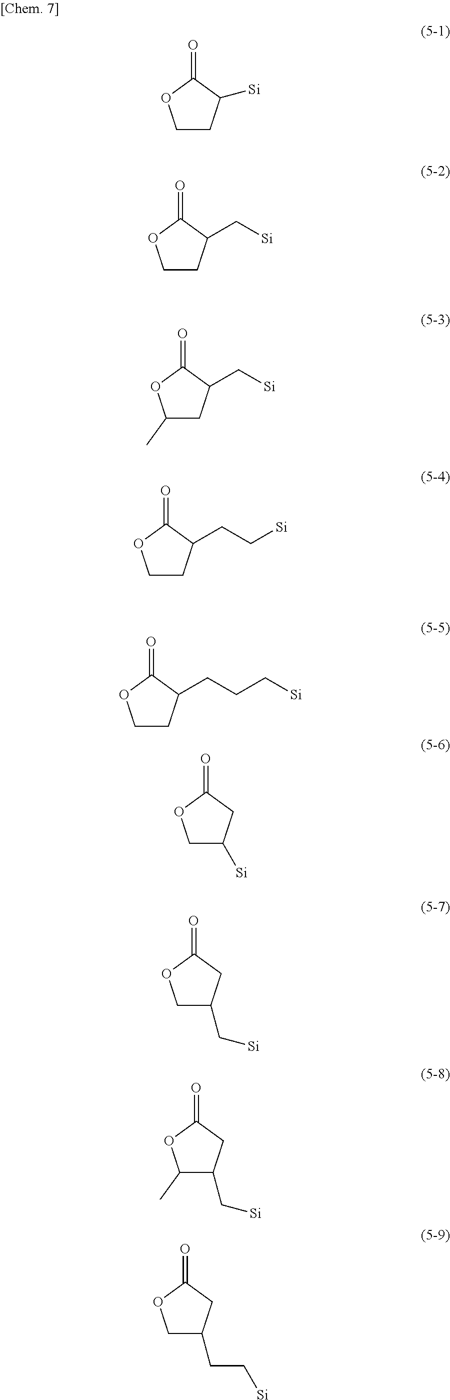

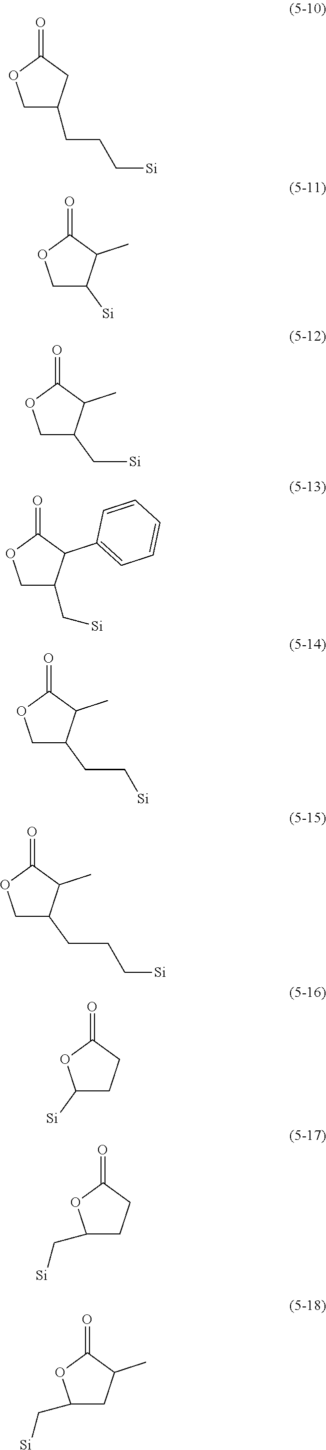

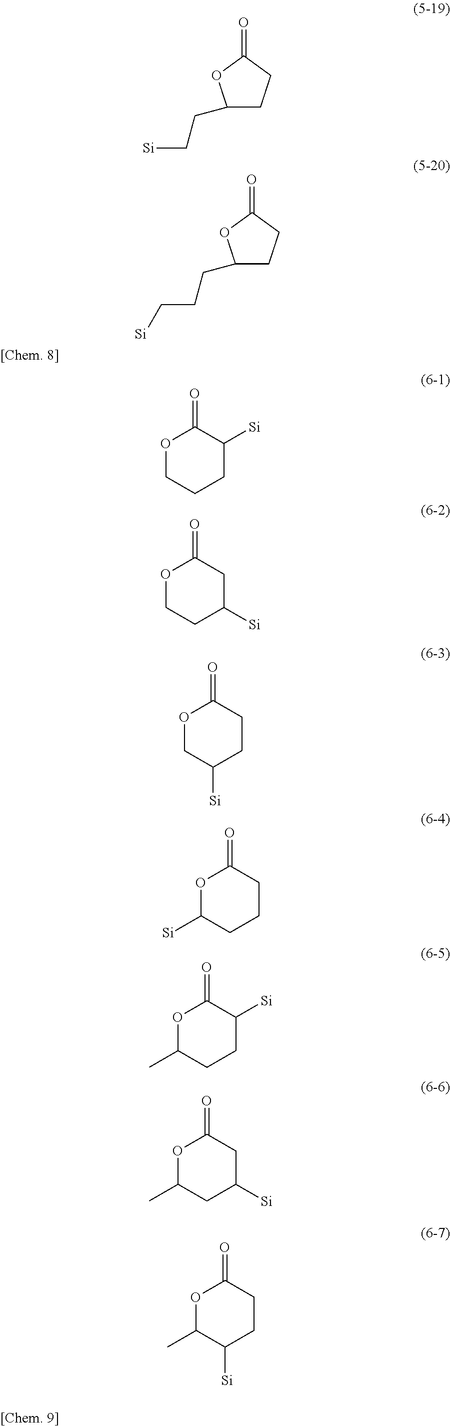

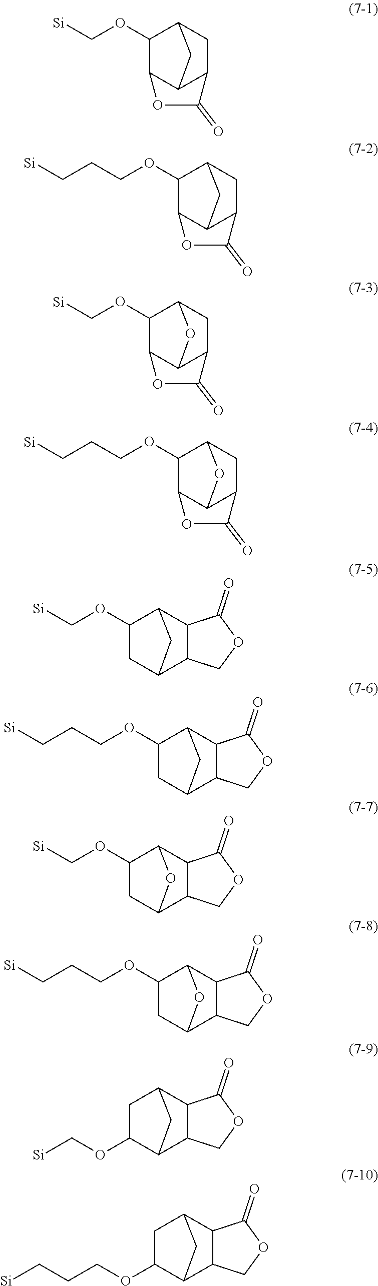

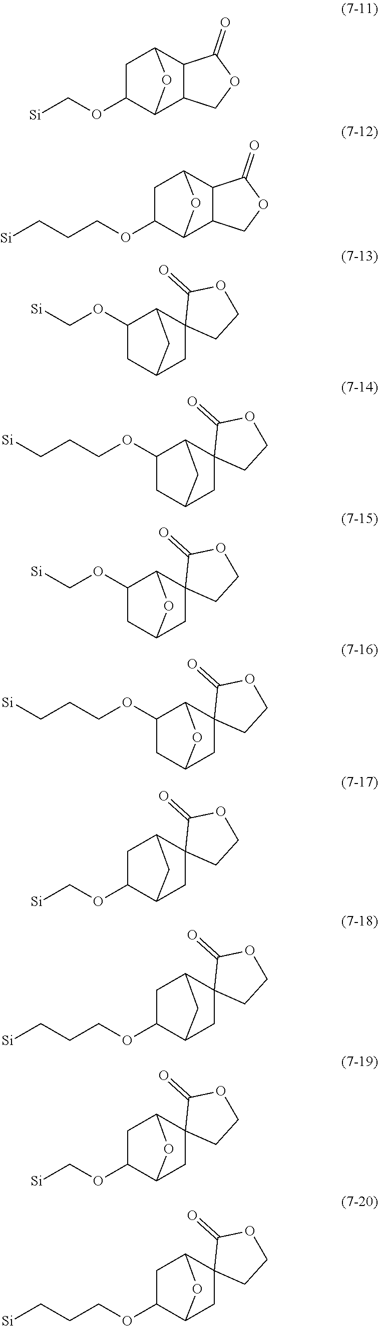

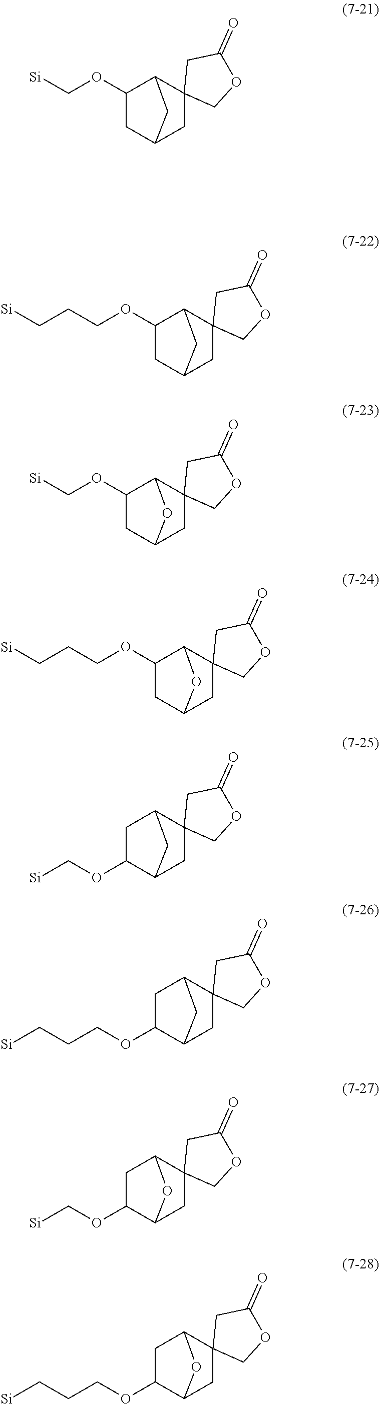

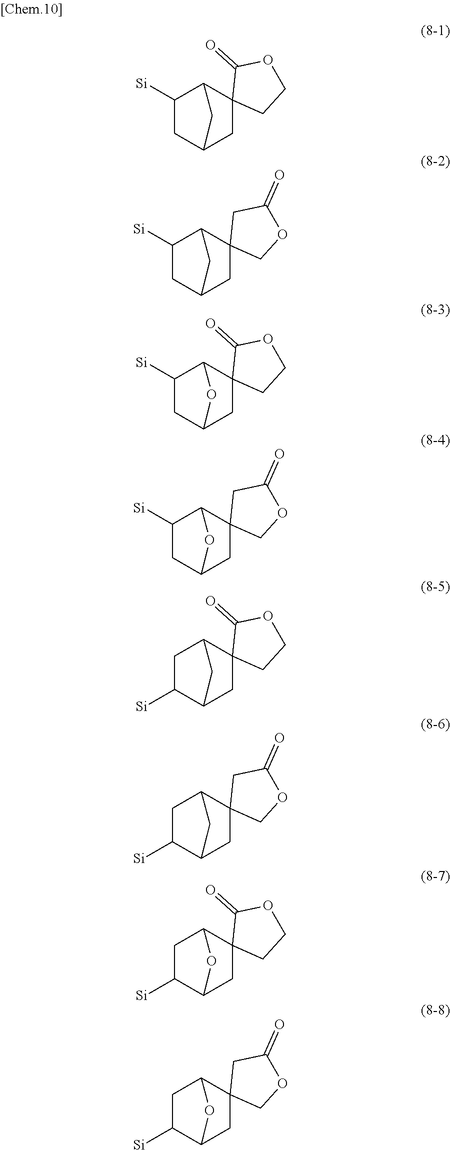

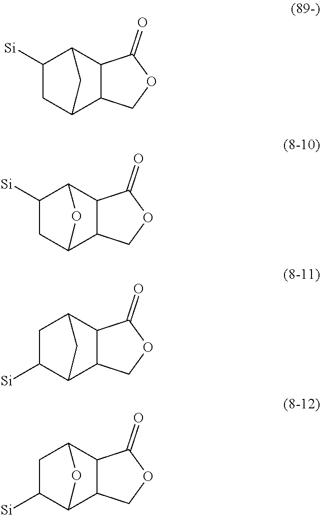

Preferable examples of a monomer (raw material) corresponding to the constitutional unit represented by General Formula (3) include tetraalkoxysilane, tetrahalosilane (for example, tetrachlorosilane, tetramethoxysilane, tetraethoxysilane, tetra-n-propoxysilane, tetraisopropoxysilane, or the like), and an oligomer of these compounds.

The weight average molecular weight of the polymer is not particularly limited, and is, for example, 500 to 50,000, preferably 800 to 40,000, and more preferably 1,000 to 30,000.

The ratio (copolymerization ratio) of each constitutional unit in the polymer may be appropriately adjusted according to the use of the polymer. Hereinafter, as an example, the ratio of each constitutional unit which is preferable in a case where the polymer is applied to the following method for producing a cured film or method for producing a substrate with a pattern is shown.

The content ratio (copolymerization ratio) of the constitutional unit represented by General Formula (1) is preferably 10 to 60 mol %, and more preferably 20 to 50 mol %.

From the viewpoint of further improving sensitivity by allowing a larger amount of the second sensitizing element to be present in the film, the content ratio (copolymerization ratio) of the constitutional unit represented by General Formula (1-A) is preferably 10 to 60 mol %, and more preferably 20 to 50 mol %.

In a case where the polymer has the constitutional unit represented by General Formula (2), the content ratio (copolymerization ratio) thereof is preferably 10 to 60 mol %, and more preferably 20 to 50 mol %.

In a case where the polymer has the constitutional unit represented by General Formula (3), the content ratio (copolymerization ratio) thereof is preferably 10 to 60 mol %, and more preferably 20 to 50 mol %.

### (Method for Obtaining Polymer)

The polymer can be synthesized, for example, by conducting hydrolysis and polycondensation of halosilane, alkoxysilane, an alkoxide containing an element represented by M in General Formula (1-A), a halide, and the like (hereinafter, collectively referred to as “raw material compounds corresponding to each constitutional unit”).

As a specific procedure for the synthesis, first, the raw material compounds corresponding to each constitutional unit are collected in a reaction vessel at room temperature (in particular, an ambient temperature not heated and not cooled, and usually about 15° C. to 30° C.; the same shall apply hereinafter). Thereafter, water for hydrolyzing the raw material compounds corresponding to each constitutional unit, a catalyst for causing the polycondensation reaction to proceed, and, if desired, a reaction solvent are added to the reaction vessel to form a reaction solution. The addition order at this time is not particularly limited thereto.

Next, the reaction solution is stirred, and the hydrolysis and condensation reaction are allowed to proceed at a predetermined temperature for a predetermined period of time. In this manner, a resin can be obtained. The time required for the reaction depends on the type of the catalyst, and is usually 3 to 24 hours, and the reaction temperature is room temperature (for example, 25° C.) or higher and 200° C. or lower.

In a case where heating is performed, in order to prevent the unreacted raw material, water, the reaction solvent, and/or the catalyst in the reaction system from being distilled off to the outside of the reaction system, it is preferable that the reaction vessel is a closed system or a reflux device is attached to reflux the reaction system. After the reaction, from the viewpoint of handling of the resin composition, it is preferable to reduce water remaining in the reaction system, the alcohol to be formed, and the catalyst. Examples of the specific method include (i) an extraction operation and (ii) a method in which a solvent, such as toluene, which does not adversely affect the reaction, is added to the reaction system and azeotropically removed in a Dean-Stark tube.

The amount of water used in the hydrolysis and condensation reactions is not particularly limited. From the viewpoint of reaction efficiency, the amount is preferably 0.01 to 15 times with respect to the total number of moles of the hydrolyzable groups (an alkoxy group or a halogen atom group, and in a case of including both, an alkoxy group and a halogen atom group) contained in the raw material compounds corresponding to each constitutional unit.

The catalyst for causing the polycondensation to proceed is not particularly limited. As the catalyst, an acid catalyst or a base catalyst is preferably used.

Specific examples of the acid catalyst include hydrochloric acid, nitric acid, sulfuric acid, hydrofluoric acid, phosphoric acid, acetic acid, oxalic acid, trifluoroacetic acid, methanesulfonic acid, trifluoromethanesulfonic acid, camphorsulfonic acid, benzenesulfonic acid, tosylic acid, a polyvalent carboxylic acid such as formic acid, maleic acid, malonic acid, or succinic acid, or anhydrides thereof.

Specific examples of the base catalyst include triethylamine, tripropylamine, tributylamine, tripentylamine, trihexylamine, triheptylamine, trioctylamine, diethylamine, triethanolamine, diethanolamine, sodium hydroxide, potassium hydroxide, sodium carbonate, and tetramethylammonium hydroxide. The amount of the catalyst used is preferably 0.001 to 0.5 times with respect to the total number of moles of the hydrolyzable groups (an alkoxy group or a halogen atom group, and in a case of including both, an alkoxy group and a halogen atom group) contained in the raw material compounds corresponding to each constitutional unit.

In the reaction, the reaction solvent is not necessarily used, and the raw material compound, water, and the catalyst can be mixed and hydrolyzed and condensed. On the other hand, in a case where a reaction solvent is used, the type thereof is not particularly limited. Among these, from the viewpoint of solubility of the raw material compound, water, and the catalyst, a polar solvent is preferable, and an alcohol-based solvent is more preferable. Specifically, one or two or more of methanol, ethanol, 1-propanol, 2-propanol, 1-butanol, 2-butanol, diacetone alcohol, and propylene glycol monomethyl ether may be used. As the amount to be used in a case where the reaction solvent is used, any amount necessary for the hydrolysis condensation reaction to proceed in a homogeneous system can be used.

It is preferable to reduce unreacted monomers and impurities in the synthesized polymer by a method commonly known in the field of polymer chemistry, such as dilution with a solvent, concentration, extraction, washing with water, ion exchange resin purification, filtration, or the like.

### (Solvent)

In the first embodiment, the above polymer and the solvent having a 1-octanol/water partition coefficient log P_{ow} of 3 or less are used in combination.

From the viewpoint of better solubility of the polymer, the log P_{ow} is preferably 2.5 or less, more preferably −2.0 to 2.5, still more preferably −1.5 to 2.5, and particularly preferably −1.0 to 2.0.

In a case where the log P_{ow} of the solvent is described in a catalog of the solvent or a safety data sheet (SDS), the value can be adopted. In a case where log P_{ow} is not described in the catalog or SDS, the log P_{ow} can be measured according to JIS Z 7260-107.

The resin composition according to the first embodiment may contain a solvent having a log P_{ow} of more than 3, in addition to the solvent having a log P_{ow} of 3 or less, as long as the polymer is dissolved. However, from the viewpoint of good solubility of the polymer, the ratio of the solvent having a log P_{ow} of 3 or less in the total solvent is preferably 50% by mass or more, more preferably 60% by mass or more, still more preferably 70% by mass or more, and particularly preferably 80% by mass or more. Only a solvent having a log P_{ow} of 3 or less may be used as the solvent. In addition, two or more solvents having a log P_{ow} of 3 or less may be used in combination.

Examples of a preferable solvent include glycol ethers, alcohols, esters, and ketones. From these solvents, a solvent having a particularly log P_{ow} of 3 or less can be preferably used.

In the present specification, glycol ethers refer to compounds in which at least one terminal (hydroxy terminal) of glycol is replaced with an ether bond. Specific examples of the glycol ethers include ethylene glycol monomethyl ether, ethylene glycol monoethyl ether, ethylene glycol mono-n-butyl ether, ethylene glycol dimethyl ether, ethylene glycol monomethyl ether acetate, ethylene glycol monoethyl ether acetate, ethylene glycol monobutyl ether acetate, diethylene glycol monomethyl ether, diethylene glycol monoethyl ether, diethylene glycol mono-n-butyl ether, diethylene glycol dimethyl ether, diethylene glycol monoethyl ether acetate, diethylene glycol monobutyl ether acetate, propylene glycol monomethyl ether, propylene glycol mono-n-butyl ether, propylene glycol monomethyl ether acetate, dipropylene glycol methyl ether acetate, and methyl-1,3-butylene glycol acetate.

Specific examples of the alcohols include chain alcohols such as methanol, ethanol, 1-propanol, 2-propanol, 1-butanol, 1-pentanol, 1-hexanol, 4-methyl-2-pentanol, 1-heptanol, 1-octanol, 1-nonanol, and structural isomers thereof; and cyclic alcohols such as cyclobutanol, cyclopentanol, cyclohexanol, and tetrahydrofurfuryl alcohol.

In the present specification, the esters do not correspond to the above-described glycol ethers, and refer to compounds having an ester bond. Specific examples of the esters include methyl acetate, ethyl acetate, n-propyl acetate, isopropyl acetate, n-butyl acetate, isobutyl acetate, n-pentyl acetate, isopentyl acetate, ethylene glycol diacetate, propylene glycol diacetate, 1,4-butanediol diacetate, 1,3-butylene glycol diacetate, 1,6-hexanediol diacetate, cyclohexyl acetate, triacetin, γ-butyrolactone, and γ-valerolactone.

Specific examples of the ketones include acetone, methyl ethyl ketone, methyl isobutyl ketone, methyl amyl ketone, 2-heptanone, 4-heptanone, 2-octanone, cyclopentanone, cyclohexanone, cycloheptanone, acetyl acetone, and dioxane.

The amount of the solvent used (in a case of using a plurality of types of solvents, the total amount thereof) is not particularly limited, but the solvent can be used in an amount such that the non-volatile component concentration is, for example, 1% to 50% by mass, preferably 1% to 40% by mass, and more preferably 5% to 30% by mass. The non-volatile component concentration may be appropriately adjusted in consideration of the thickness of the resin film to be formed and the solubility of the polymer.

### (Number of Particles in Resin Composition)

The uniformity of the resin composition can be quantitatively determined, for example, by the number of particles in the resin composition.

In the resin composition of the first embodiment, in the particle measurement with a light scattering type liquid-borne particle detector, the number of particles having a particle diameter of more than 0.2 μm is preferably 100 or less, more preferably 50 or less, and still more preferably 25 or less per 1 mL.

The number of particles having a particle diameter of more than 0.2 μm is ideally 0 per 1 mL. However, practically, the lower limit value of the number of particles having a particle diameter of more than 0.2 μm is, for example, 1 per 1 mL, and is 3 per 1 mL as a specific example.

The number of particles having a particle diameter of more than 0.2 μm can be measured using a commercially available measuring device capable of measuring the number of particles by a light scattering type liquid-borne particle measuring method using a laser as a light source. The particle diameter of the particles means a light scattering equivalent diameter based on a latex formed of polystyrene (PSL) standard particle.

### (Method for Producing Resin Composition)

The resin composition of the first embodiment can be preferably produced through
a solution forming step of mixing the polymer obtained by hydrolysis and polycondensation of a silicon compound represented by General Formula (1y) and a metal compound represented by General Formula (1-2) and a solvent having a 1-octanol/water partition coefficient of 3 or less to form a solution.

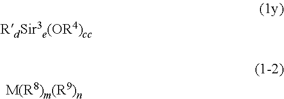

In General Formula (1y),
in a case where a plurality of R's are present, R's are each independently an aryl group or an aralkyl group,
the definition and specific aspects of R³ are the same as those for R³ in General Formula (1),
the definition and specific aspects of R⁴ are the same as those for R⁴ in General Formula (1),
d is a number of 1 or more and 3 or less, e is a number of 0 or more and 2 or less, cc is a number of 1 or more and less than 4, and d+e+cc=4.

In General Formula (1-2),
the definition and specific aspects of M are the same as those for M in General Formula (1-A),
in a case where a plurality of R³'s are present, R³'s are each independently a hydrogen atom, a hydroxy group, a linear or branched aliphatic hydrocarbon group, or an aromatic hydrocarbon group,
in a case where a plurality of R⁹'s are present, R⁹'s are each independently an alkoxy group or halogen,
m is a number of 0 or more and 3 or less, n is a number of 1 or more and 4 or less, and m+n is 3 or 4.

Specific aspects of R′ can be the same as the specific aspects of R² in General Formula (1).

Specific aspects of R⁸ can be the same as the specific aspects of R¹ in General Formula (1-A).

Specific examples of the alkoxy group of R⁹ include a group represented by —O—R^{9′}. Here, R^{9′} is the alkyl group exemplified as the specific example of R² to R⁴ in General Formula (1). The alkoxy group of R⁹ preferably has 1 to 5 carbon atoms, and specifically, a methoxy group or an ethoxy group is preferable. The halogen of R⁹ is preferably a fluorine atom or a chlorine atom.

According to the knowledge of the present inventors, even in a case where the polymer includes a component (precipitate or the like) which is insoluble or slightly soluble in the polymerization solvent immediately after the polymerization, by performing the solution forming step, the insoluble or slightly soluble component is dissolved, and a homogeneous solution can be obtained.

Specific aspects of the “solvent having a 1-octanol/water partition coefficient of 3 or less” used in the solution forming step are as described in the section of (Solvent).

The stirring condition and the temperature condition in the solution forming step are not particularly limited as long as a homogeneous solution can be finally obtained. Incidentally, in the solution forming step, ultrasonic waves may be applied in order to promote dissolution.

In obtaining the above polymer, it is preferable to use a chelating agent. It is considered that the use of the chelating agent improves the reaction uniformity.

Examples of the chelating agent include B-diketones such as acetylacetone, benzoylacetone, and dibenzoylmethane, and B-keto acid esters such as ethyl acetoacetate and ethyl benzoylacetate.

After the solution forming step, further, at least one operation selected from the group consisting of dilution with a solvent, concentration, extraction, washing with water, purification with an ion exchange resin, and filtration may be performed.

Examples of the concentration include general methods such as an evaporator.

As the extraction, a general method such as using a separatory funnel can be used. In the production of the polymer described above, the water remaining in the system after the hydrolysis and polycondensation reaction, the alcohol to be formed, and the catalyst may be removed by the extraction.

In a case where the polymer is separated into another layer from water, the polymer may be washed with water.

The polymer may be dissolved in a solvent that is separated into another layer from water to form an organic solution and then washed with water.

Ion exchange resin purification can be performed to reduce the metal content in the system by contacting with a commercially available ion exchange resin.

Filtration may be performed to reduce insolubles such as particles in the system by general methods.

### Second Embodiment: Resin Composition

A resin composition according to a second embodiment contains
a polysiloxane compound having a constitutional unit represented by General Formula (1),
a polymetalloxane compound having a constitutional unit represented by General Formula (1-A), and
a solvent having a 1-octanol/water partition coefficient log P_{ow} of 3 or less.

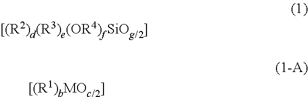

In General Formula (1),
in a case where a plurality of R²'s are present, R²'s are each independently an aryl group or an aralkyl group,
in a case where a plurality of R³'s are present, R³'s are each independently a hydrogen atom, a linear or branched aliphatic hydrocarbon group, or an aromatic hydrocarbon group,
in a case where a plurality of R⁴'s are present, R⁴'s are each independently a hydrogen atom or a linear or branched aliphatic hydrocarbon group,
d is a number of 1 or more and 3 or less, e is a number of 0 or more and 2 or less, f is a number of 0 or more and less than 3, g is a number of more than 0 and 3 or less, and d+e+f+g=4.

In General Formula (1-A),
M is at least one selected from the group consisting of Fe, Co, Ni, Cu, Zn, Ga, Ge, Mo, Pd, Ag, Sn, Cs, Ba, W, and Hf,
in a case where a plurality of R's are present, R's are each independently a hydrogen atom, a hydroxy group, a halogen group, an alkoxy group, a linear or branched aliphatic hydrocarbon group, or an aromatic hydrocarbon group,
b is a number of 0 or more and less than 6, c is a number of more than 0 and 6 or less, and b+c=3 to 6.

The resin composition of the second embodiment can also be a homogeneous resin composition. The reason for this is considered to be the same reason as the reason described in the first embodiment.

In the second embodiment, the specific aspects of the atomic groups in General Formula (1) and the specific aspects of the subscripts (d, e, f, and g) are the same as those in the first embodiment.

In the second embodiment, the specific aspects of the atomic group in General Formula (1-A) and the specific aspects of the subscripts (b) and (c) are the same as those in the first embodiment.

In the second embodiment, the polysiloxane compound may further include the constitutional unit represented by General Formula (2) and/or General Formula (3) described in the first embodiment. The polysiloxane compound may further include another constitutional unit.

In the second embodiment, the polymetalloxane compound may further include the constitutional unit represented by General Formula (2) and/or General Formula (3) described in the first embodiment. The polymetalloxane compound may further include another constitutional unit.

In the second embodiment, a method for obtaining the polysiloxane compound and a method for obtaining the polymetalloxane compound can refer to the method for obtaining the polymer in the first embodiment.

Specific types and amount of the solvent which can be contained in the resin composition according to the second embodiment, and other solvents can be the same as those described in the first embodiment.

The number of particles in the resin composition according to the second embodiment can also be the same as that of the first embodiment.

<Aspect in which Resin Composition is Photosensitive>

The resin composition according to the first or second embodiment can further contain a photoinduced compound. In other words, the resin composition according to the first or second embodiment can have photosensitivity.

As the photoinduced compound, for example, at least one selected from the group consisting of naphthoquinone diazide, a photoacid generator, a photobase generator, and a photoradical generator can be used.

When exposed to light, the quinonediazide compound releases nitrogen molecules and decomposes to generate a carboxylic acid group in the molecule, thereby improving the solubility of the photosensitive resin film obtained from the resin composition described above in an alkaline developer. In addition, the alkali solubility of the photosensitive resin film is suppressed in the unexposed portion. Therefore, the photosensitive resin film containing the quinonediazide compound has a contrast of solubility in the alkaline developer in the unexposed and exposed portions, so that a positive pattern can be formed.

For example, the quinonediazide compound is a compound having a quinonediazide group, such as 1,2-quinonediazide group. Examples of the 1,2-quinonediazide compound include 1,2-naphthoquinone-2-diazide-4-sulfonic acid, 1,2-naphthoquinone-2-diazide-5-sulfonic acid, 1,2-naphthoquinone-2-diazide-4-sulfonyl chloride, and 1,2-naphthoquinone-2-diazide-5-sulfonyl chloride. Using the quinonediazide compound makes it possible to obtain a positive photosensitive resin film that is sensitive to an i-line (wavelength 365 nm), an h-line (wavelength 405 nm), and a g-line (436 nm) of a mercury lamp, which are common ultraviolet rays.

Examples of a commercially available quinonediazide compound include NT series, 4NT series, and PC-5, manufactured by Toyo Gosei Co., Ltd., TKF series and PQ-C, manufactured by SANBO CHEMICAL IND. CO., LTD.

In a case where the quinonediazide compound is used as the photoinduced compound, the blending amount thereof is preferably 1 part by mass or more and 30 parts by mass or less, and more preferably 5 parts by mass or more and 20 parts by mass or less with respect to 100 parts by mass of the polymer. Using an appropriate amount of the quinonediazide compound makes it easy to achieve both sufficient patterning performance and optical properties such as transparency and refractive index of the obtained patterned cured film.

Here, the “polymer” refers to the above-described polymer, polysiloxane compound, and polymetalloxane compound. The same applies to the following.

The photoacid generator will be described. The photoacid generator is a compound that generates an acid upon irradiation with light, and it is considered that the acid generated at the exposed portion promotes the silanol condensation reaction, that is, the sol-gel polymerization reaction, and the dissolution rate by the alkaline developer is remarkably lowered. In addition, in a case where an epoxy group or oxetane group is included, it is preferable to accelerate each curing reaction. On the other hand, the unexposed portion is dissolved by the alkaline developer without causing this action, and a negative pattern corresponding to the shape of the exposed portion is formed.

Specific examples of the photoacid generator include a sulfonium salt, an iodonium salt, sulfonyl diazomethane, N-sulfonyloxyimide, and oxime-O-sulfonate. These photoacid generators may be used alone or in a combination of two or more thereof. Specific examples of the commercially available products include product name: Irgacure 290, Irgacure PAG121, Irgacure PAG103, Irgacure CGI1380, and Irgacure CGI725 (all manufactured by BASF USA Ltd.); product name: PAI-101, PAI-106, NAI-105, NAI-106, TAZ-110, and TAZ-204 (all manufactured by Midori Kagaku Co., Ltd.); product name: CPI-200K, CPI-210S, CPI-101A, CPI-110A, CPI-100P, CPI-110P, CPI-310B, CPI-100TF, CPI-110TF, HS-1, HS-1A, HS-1P, HS-1N, HS-1TF, HS-1NF, HS-1MS, HS-1CS, LW-Si, and LW-S1NF (all manufactured by San-Apro Ltd.); and product name: TFE-triazine, TME-triazine, and MP-triazine (all manufactured by Sanwa Chemical Co., Ltd.).

The blending amount of the photoacid generator as the photoinduced compound is preferably 0.01 parts by mass or more and 10 parts by mass or less, and more preferably 0.05 parts by mass or more and 5 parts by mass or less with respect to 100 parts by mass of the polymer. In a case where an appropriate amount of the photoacid generator is used, it is easy to achieve both sufficient patterning performance and storage stability of the composition.

The photobase generator will be described. The photobase generator is a compound that generates a base (anion) upon irradiation with light, and the base generated in the exposed portion causes the sol-gel reaction to proceed, so that the dissolution rate by the alkaline developer is remarkably lowered, that is, resistance to the alkaline developer can be realized. On the other hand, the unexposed portion is dissolved by the alkaline developer without causing this action, and a negative pattern corresponding to the shape of the exposed portion is formed.

Specific examples of the photobase generator include amides and amine salts. Specific examples of the commercially available product include product name: WPBG-165, WPBG-018, WPBG-140, WPBG-027, WPBG-266, WPBG-300, and WPBG-345 (manufactured by FUJIFILM Wako Pure Chemical Corporation), 2-(9-Oxoxanthen-2-yl)propionic Acid 1,5,7-Triazabicyclo[4.4.0]dec-5-ene Salt, 2-(9-Oxoxanthen-2-yl)propionic Acid, Acetophenone 0-Benzoyloxime, 2-Nitrobenzyl Cyclohexylcarbamate, and 1,2-Bis(4-methoxyphenyl)-2-oxoethyl Cyclohexylcarbamate (manufactured by Tokyo Chemical Industry Co., Ltd.), and product name: EIPBG, EITMG, EINAP, and NMBC (manufactured by EIWEISS Chemical Corporation).

The blending amount of the photobase generator as a photoinduced compound is preferably 0.01 parts by mass or more and 10 parts by mass or less, and more preferably 0.05 parts by mass or more and 5 parts by mass or less with respect to 100 parts by mass of the polymer. By using an appropriate amount of the photobase generator, the balance of the resist liquid resistance of the obtained patterned cured film and the storage stability of the composition can be further improved.

### <Method for Producing Cured Film>

A cured film can be produced using the resin composition according to the first embodiment or the second embodiment.

Specifically, a cured film can be produced by a series of steps including
a resin film forming step of applying the resin composition of the first embodiment or the second embodiment onto a substrate to form a resin film, and
a heating step of heating the resin film at a temperature of 80° C. or higher and 350° C. or lower.

The resin film can be formed by a known coating method. The resin film is preferably applied onto the substrate by a spin coating method.

<Substrate with Multilayer Film>

A substrate with a multilayer film can be produced using the resin composition according to the first embodiment or the second embodiment.

Specifically, the substrate with a multilayer film can be produced using the resin composition of the first embodiment or the second embodiment, and the substrate with a multilayer film includes
a substrate,
an organic layer that is provided on one surface of the substrate,
a resist underlayer film which is a cured film of the resin composition of the first embodiment or the second embodiment and is provided on a surface of the organic layer opposite to the substrate, and
a resist layer that is provided on a surface of the resist underlayer film opposite to the organic layer.

An example of the substrate with a multilayer film is shown in SO of FIG. 1.

The substrate 100 with a multilayer film includes, for example, an organic layer 103 on a base material 101, an underlayer film 105 of a resist, which is a cured product of the resin composition according to the first embodiment or the second embodiment, on the organic layer 103, and a resist layer 107 on the underlayer film 105.

A method for producing the substrate with a multilayer film will be described.

First, the base material 101 is prepared. The base material 101 is selected from a silicon wafer, a metal, a glass, a ceramic, or a plastic base material according to the application of the substrate with a pattern to be formed.

Specific examples of the base material used in a semiconductor or a display include silicon, silicon nitride, glass, polyimide (Kapton), polyethylene terephthalate, polycarbonate, and polyethylene naphthalate. In addition, the base material 101 may have any layer such as silicon, metal, glass, ceramic, or resin on the surface thereof.

Next, an organic application liquid for forming the organic layer 103 is applied onto the base material 101. The organic application liquid used to form the organic layer 103 includes, for example, an application liquid containing a novolac resin having a phenol structure, a bisphenol structure, a naphthalene structure, a fluorene structure, and a carbazole structure and the like, epoxy resin, urea resin, isocyanate resin, or polyimide resin but is not particularly limited thereto. In addition, the thickness of the organic layer 103 can be 5 nm or more and 20,000 nm or less.

As a method of applying the organic application liquid onto the base material 101, a known coating method such as spin coating, dip coating, spray coating, bar coating, application, ink jet, or roll coating can be used without any particular limitation.

Thereafter, the organic layer 103 can be obtained by heating the base material 101 to which the organic application liquid is applied. The heat treatment may be performed under conditions such that the solvent can be removed to an extent that the obtained organic layer 103 does not easily flow or is not easily deformed, for example, at 100° C. to 400° C. and for 30 seconds or longer and 30 minutes or shorter.

The resin composition is applied onto the organic layer 103 and cured. In this manner, the underlayer film 105 of the resist can be obtained. As a method of applying the resin composition, the above-described applying method can be used. In addition, the resin composition can be solidified by heating at a temperature of 80° C. or higher and 350° C. or lower to form the underlayer film 105.

The thickness of the underlayer film 105 can be 5 nm or more and 500 nm or less.

The resist layer 107 can be formed by applying a resist liquid onto the underlayer film 105 and heating the resist liquid. A resist material that can be used for the substrate 100 with a multilayer film is not particularly limited. In the present embodiment, the resist layer 107 may be formed of a positive resist material or a negative resist material.

Through the above steps, the substrate 100 with a multilayer film can be formed.

<Method for Producing Substrate with Pattern>

A substrate with a pattern can be produced using the substrate 100 with a multilayer film. This will be described with reference to FIG. 1.

A method for preparing a substrate 150 with a pattern can include the following 0th to 5th steps.

0th step: a step of preparing the substrate 100 with a multilayer film.

First step: a step of exposing the resist layer 107 through a light shielding plate (photomask) 109 and then developing the exposed resist layer 107 using a developer to obtain a pattern.

Second step: a step of dry-etching the underlayer film 105 through the pattern of the resist layer 107 to obtain a pattern of the underlayer film 105.

Third step: a step of dry-etching the organic layer 103 through the pattern of the underlayer film 105 to obtain a pattern of the organic layer 103.

Fourth step: a step of dry-etching the base material 101 through the pattern of the organic layer 103 to obtain a pattern of the base material 101.

Fifth step: a step of removing the organic layer 103 to obtain the substrate 150 with a pattern.

Hereinafter, each step will be described with reference to FIG. 1.

### (0th Step)

The step of preparing the substrate 100 with a multilayer film (step S0) can be performed according to the step of producing the substrate 100 with a multilayer film described above.

### (First Step)

The substrate 100 with a multilayer film prepared in the 0th step is shielded with a light shielding plate (photomask) 109 having a desired shape for forming a desired pattern, and then the resist layer 107 is irradiated with light and subjected to an exposure treatment. In this manner, the exposed resist layer 107 is obtained. The exposed resist layer 107 includes an exposed portion, which is a portion exposed to light, and an unexposed portion, which is a portion not exposed to light.

A known method can be used for the exposure treatment. A light beam having a wavelength in a range of 1 nm to 600 nm can be used as a light source. Specifically, a low-pressure mercury lamp, a high-pressure mercury lamp, an ultra-high-pressure mercury lamp, a KrF excimer laser (wavelength 248 nm), an ArF excimer laser (wavelength 193 nm), an EUV beam (wavelength 6 nm to 27 nm, preferably 13.5 nm), or the like can be used.

The exposure amount can be adjusted according to the type and amount of the photoinduced compound to be used, the production step, and the like. As an example, the exposure amount is about 1 to 10,000 mJ/cm², and preferably about 10 to 5,000 mJ/cm².

In a case where the underlayer film 105 disposed immediately below the resist layer 107 is formed of the resin composition according to the first or second embodiment, the underlayer film 105 contains a metal species having high EUV absorbance. Therefore, the secondary electrons can flow from the underlayer film 105 to the resist 107 layer side, and the EUV photosensitivity can be increased.

After the exposure, post-exposure heating can be performed before the developing step as necessary. Incidentally, the temperature of the post-exposure heating may be set within a temperature range suitable for the resist material to be used. In addition, the post-exposure heating may be performed within a time suitable for the resist material to be used.

The exposed portion is removed by developing the exposed resist layer 107, so that a pattern having a desired shape can be formed (step S1. In addition, although FIG. 1 is an explanatory diagram of a method for producing a positive patterned cured film, when a negative patterned cured film is obtained, portions other than the exposed portion are removed by developing and are not shielded by the light shielding plate 109, that is, the resist layer 107, which is a so-called exposed portion, becomes a pattern.

Development means to form a pattern by dissolving and washing and removing an unexposed portions or exposed portions using an alkaline solution as a developer. Incidentally, as the developer, a developer containing an organic solvent as a main component is also known.

As the developing method, a known method such as an immersion method, a puddle method, or a spraying method can be used. The development time can be set according to the resist material. Then, washing, rinsing, drying, and the like are carried out as necessary.

In this manner, a pattern of the resist layer 107 can be formed.

Examples of the organic solvent-based developer include developers containing a ketone-based solvent, an ester-based solvent, an alcohol-based solvent, or the like as a main component.

Specific examples include developers containing, as a main component, acetophenone, methyl acetophenone, diisobutyl ketone, 2-hexanone, 3-hexanone, 2-heptanone, 3-heptanone, 4-heptanone, 2-octanone, 2-nonanone, methylcyclohexanone, propyl formate, butyl formate, isobutyl formate, pentyl formate, isopentyl formate, propyl acetate, butyl acetate, isobutyl acetate, pentyl acetate, isopentyl acetate, 2-methylbutyl acetate, hexyl acetate, butenyl acetate, methyl propionate, ethyl propionate, methyl lactate, ethyl lactate, propyl lactate, butyl lactate, isobutyl lactate, pentyl lactate, isopentyl lactate, ethyl 3-ethoxypropionate, methyl 2-hydroxyisobutyrate, ethyl 2-hydroxyisobutyrate, methyl crotonate, ethyl crotonate, methyl valerate, methyl pentenoate, methyl benzoate, benzyl formate, phenyl acetate, ethyl benzoate, phenylethyl formate, benzyl acetate, methyl phenylacetate, ethyl phenylacetate, 2-phenylethyl acetate, methyl 3-phenylpropionate, benzyl propionate, ethanol, 1-propanol, 2-propanol, and the like. Among these, from the viewpoint of availability and workability, butyl acetate is preferable.

These organic solvents may be used alone or as a mixture of two or more thereof. The organic solvent-based developer may contain only these organic solvents, and may contain other components in addition to the organic solvents as long as the performance as a developer is not impaired. Examples of the other components include a surfactant and the like. Examples of the surfactant include fluorine-based surfactants and silicone-based surfactants.

### (Second Step)

The dry etching of the underlayer film 105 is performed through the pattern of the resist layer 107 (step S2). In the second step, the dry etching of the underlayer film 105 can be performed with a fluorine-based gas.

In the second step, the pattern of the resist layer 107 serves as a protective film, and after dry etching, the resist layer 107 remains with a reduced thickness or disappears. In step S2 of FIG. 1, it is described that the pattern of the resist layer 107 disappears after the dry etching.

Examples of the fluorine-based gases used for dry etching of the underlayer film 105 include CF₄, CH₃F, CH₂F₂, CHF₃, C₃F₆, C₄F₆, and C₄F₈. Of course, the available gas is not limited to these.

### (Third Step)

The dry etching of the organic layer 103 is performed through the pattern of the underlayer film 105 to obtain a pattern of the organic layer 103 (step S3). In the third step, the dry etching of the organic layer 103 is preferably performed with an oxygen-based gas.

In the third step, the pattern of the underlayer film 105 serves as a protective film. After the dry etching, the underlayer film 105 remains with a reduced film thickness or disappears. In step S3 of FIG. 1, it is described that the pattern of the underlayer film 105 disappears after the dry etching.

Examples of the oxygen-based gas used for the dry etching of the organic layer 103 include O₂, CO, and CO₂. Of course, the available gas is not limited to these.

### (Fourth Step)

The dry etching of the base material 101 is performed through the pattern of the organic layer 103 to obtain a pattern of the base material 101 (step S4). In the fourth step, the dry etching of the base material can be performed with a fluorine-based gas or a chlorine-based gas. In the fourth step, the pattern of the organic layer 103 serves as a protective film, and after the dry etching, the film thickness is reduced or almost disappears. In step S4 of FIG. 1, it is described that the pattern of the organic layer 103 remains after the dry etching.

Examples of the fluorine-based gas or chlorine-based gas used for dry etching of the base material 101 include CF₄, CH₃F, CH₂F₂, CHF₃, C₃F₆, C₄F₆, C₄F₈, chlorine trifluoride, chlorine, trichloroborane, and dichloroborane. Of course, the available gas is not limited to these.

### (Fifth Step)

After the pattern is formed, the organic layer 103 is removed (in a case where the resist layer 107 and the underlayer film 105 remain, the films are also removed), so that the substrate 150 with a pattern, having a desired pattern, can be obtained (step S5).

### <Method for Producing Patterned Cured Film Using Photosensitive Resin Composition>

A patterned cured film can be produced using the above-described resin composition containing a photoinduced compound (photosensitive resin composition). This will be described with reference to FIG. 2. Incidentally, the “patterned cured film” is a cured film that is obtained by forming a pattern by development after the exposing step and curing the obtained pattern.

The method for producing the patterned cured film 211 can include the following first to fourth steps.

First step: a step of applying a photosensitive resin composition onto a base material 201 and heating the photosensitive resin composition to form a photosensitive resin film 203.

Second step: a step of exposing the photosensitive resin film 203 through a light shielding plate (photomask) 205

Third step: a step of developing the exposed photosensitive resin film 203 to form a patterned film 207.

Fourth step: a step of heating the patterned film 207 to cure the patterned film 207 and form a patterned cured film 211.

### (First Step)

The base material 201 is prepared (step S11-1). The base material 201 to which the photosensitive resin composition is applied is selected from a base material formed of a silicon wafer, metal, glass, ceramic, or plastic, depending on the application of the patterned cured film to be formed. Specific examples thereof include silicon, silicon carbide, glass, polyimide (kapton), polyethylene terephthalate, polycarbonate, and polyethylene naphthalate, as a base material used for a semiconductor, a display, or the like. The base material 201 may have any layer such as silicon, metal, glass, ceramic, or resin layer on the surface.

As a coating method on the base material 201, a known coating method such as spin coating, dip coating, spray coating, bar coating, application, ink jet, or roll coating can be used without any particular limitation.

The base material 201 to which the photosensitive resin composition is applied is heated to obtain the photosensitive resin film 203 (step S11-2). The heat treatment may be performed under conditions such that the solvent can be removed to an extent that the obtained photosensitive resin film 203 does not easily flow or is not easily deformed, for example, at 80° C. to 120° C. and for 30 seconds or longer and 5 minutes or shorter.

### (Second Step)

The photosensitive resin film 203 obtained in the first step is shielded with a light shielding plate (photomask) 205 having a desired shape for forming a desired pattern, and then the photosensitive resin film 203 is irradiated with light and subjected to an exposure treatment. In this manner, the exposed photosensitive resin film 203 is obtained (step S12). The exposed photosensitive resin film 203 includes an exposed portion 203a which is a portion exposed to light, and a portion which is not exposed to light.

A known method can be used for the exposure treatment. As a light source, a light beam having a wavelength in a range of 1 nm to 600 nm can be used. Specifically, a low-pressure mercury lamp, a high-pressure mercury lamp, an ultra-high-pressure mercury lamp, a KrF excimer laser (wavelength 248 nm), an ArF excimer laser (wavelength 193 nm), an EUV beam (wavelength 6 nm to 27 nm, preferably 13.5 nm), or the like can be used. In particular, when EUV light is used, a fine pattern can be obtained. The wavelength of the EUV light generally applied is 13.5 nm. In addition, the pulse width of the EUV light is usually 0.1 to 40 nm, and the intensity of the EUV light is usually 100 to 1,000 kW.

The exposure amount may be adjusted according to the type and amount of the photoinduced compound to be used, the production step, and the like. The exposure amount is usually about 1 to 10,000 mJ/cm² and preferably about 10 to 5,000 mJ/cm².

After the exposure, post-exposure heating can be performed before the developing step as necessary. The temperature of the post-exposure heating is preferably 60° C. to 180° C., and the time of the post-exposure heating is preferably 30 seconds to 10 minutes.

### (Third Step)

The exposed photosensitive resin film 203 obtained in the second step is developed. In this manner, the film 207 having a pattern of a desired shape (hereinafter, may be referred to as a “patterned film”) can be formed by removing portions other than the exposed portion 203a (step S13).

Incidentally, although FIG. 2 is an explanatory diagram of the method for producing a negative patterned cured film, in a case of obtaining a positive patterned cured film, the photosensitive resin film 203 is removed by developing, and the photosensitive resin film 203, which is an unexposed portion and shielded by the light shielding plate 205, becomes the patterned film 207.

Development means to form a pattern by dissolving and washing and removing an unexposed portions or exposed portions using an alkaline solution as a developer. Incidentally, as the developer, a developer containing an organic solvent as a main component is also known. The developer used is not particularly limited as long as a desired pattern can be formed.

As the developing method, a known method such as an immersion method, a puddle method, or a spraying method can be used. The development time can be set according to the resist material. Then, washing, rinsing, drying, and the like are carried out as necessary.

### (Fourth Step)

The patterned film 207 obtained in the third step is subjected to a heat treatment to obtain the final patterned cured film 211 (step S14). The heating temperature at this time is preferably 80° C. or higher and 400° C. or lower, and more preferably 100° C. or higher and 350° C. or lower. The heat treatment time may be 1 minute or longer and 90 minutes or shorter, preferably 5 minutes or longer and 60 minutes or shorter. By appropriate heating, the desired chemical solution resistance, heat resistance, transparency, and the like can be obtained.

Although the embodiments of the present invention have been described above, these are examples of the present invention, and various configurations other than the above can be adopted. Further, the present invention is not limited to the above-described embodiments, and modifications, improvements, and the like within a range in which the object of the present invention can be achieved are included in the present invention.

### EXAMPLES

A detailed description will be given of embodiments of the present invention based on Examples and Comparative Examples. It should be noted that the present invention is not limited to Examples only.

### Hydrolysis Polycondensation Example 1

0.77 g (3.2 mmol) of phenyltriethoxysilane (hereinafter, sometimes referred to as “Ph-Si”), 1.33 g (6.4 mmol) of tetraethoxysilane (hereinafter, sometimes referred to as “TEOS”), 1.62 g (6.4 mmol) of germanium tetraethoxide (hereinafter, sometimes referred to as “TEOG”), and 3.0 g of ethanol were added to a reaction vessel, and the mixture was stirred at 70° C.

Thereafter, a mixed solution of 3.0 g of ethanol, 0.14 g (8.0 mmol) of pure water, and 0.1 g (0.8 mmol) of maleic acid was added dropwise thereto. A white precipitate was produced in the reaction vessel by the dropwise addition. The solid content concentration (slurry concentration) of the liquid containing the white precipitate was 50% by mass.

### Hydrolysis Polycondensation Example 2

3.11 g (9.4 mmol) of pentafluorophenyltriethoxysilane (hereinafter, sometimes referred to as “F5Ph-Si”), 3.94 g (18.9 mmol) of TEOS, 4.78 g (18.9 mmol) of TEOG, and 12.0 g of ethanol were added to the reaction vessel, and the mixture was stirred at 70° C.

Thereafter, a mixed solution of 36.0 g of ethanol, 0.96 g (53.3 mmol) of pure water, and 0.2 g (2 mmol) of maleic acid was added dropwise thereto. A white precipitate was produced in the reaction vessel by the dropwise addition. The solid content concentration (slurry concentration) of the liquid containing the white precipitate was 9% by mass.

### Examples 1-1 to 1-11 and Comparative Examples 1-1 to 1-3

Solubility was evaluated by adding 5.0 g of the additive solvent for solution formation or the comparative solvent shown in Table 1 to 1.0 g (slurry concentration: 50% by mass) of the liquid containing the white precipitate obtained in Hydrolysis Polycondensation Example 1. Specifically, evaluation was performed according to the following criteria.

### <Evaluation of Solubility>

### (1) Solubility and Insolubility

The additive solvent for solution formation or the comparative solvent was added, and the mixture was stirred at 25° C. for up to 1 hour. Thereafter, in a case where the precipitate or insoluble component was confirmed by visual observation, this case was determined as insoluble (indicated as “insoluble” in the table), and in a case where a solution was obtained, this case was determined as soluble (indicated as “soluble” in the table).

### (2) Ease of Dissolution

In the evaluation of solubility and insolubility, a compound that could be dissolved within 10 minutes from the start of addition and stirring of the additive solvent was denoted as A, a compound that could be dissolved in longer than 10 minutes and 30 minutes or shorter was denoted as B, and a compound that could be dissolved in longer than 30 minutes and 1 hour or shorter was denoted as C.

Various kinds of information are collectively shown in Table 1.

In Table 1, “PGME” represents propylene glycol monomethyl ether, “IPA” represents isopropanol (2-propanol), “PGMEA” represents propylene glycol monomethyl ether acetate, and “MIBC” represents methyl isobutyl carbinol (4-methyl-2-pentanol), respectively.

TABLE 1

| | | Additive solvent for | | | |
|---|---|---|---|---|---|
| | | solution formation (or | | | |
| | | comparative solvent) | | | |
| | | | 1- | | |
| | | | octanol/water | | |
| | Hydrolysis | | partition | Solubility | |
| | Polycondensation | | coefficient | | Ease of |
| | Example | Type | (log P_{ow}) | Solubility/Insolubility | Dissolution |
| Example 1-1 | 1 | Glycerin | −1.76 | Soluble | B |
| Example 1-2 | | Methanol | −0.82 | Soluble | A |
| Example 1-3 | | PGME | −0.49 | Soluble | A |
| Example 1-4 | | Ethanol | −0.32 | Soluble | A |
| Example 1-5 | | IPA | 0.05 | Soluble | A |
| Example 1-6 | | Cyclohexane | 0.08 | Soluble | A |
| Example 1-7 | | Methyl | 0.29 | Soluble | A |
| | | ethyl | | | |
| | | ketone | | | |
| Example 1-8 | | PGMEA | 1.20 | Soluble | A |
| Example 1-9 | | MIBC | 1.43 | Soluble | A |
| Example 1-10 | | n-butyl | 1.82 | Soluble | A |
| | | acetate | | | |
| Example 1-11 | | Toluene | 2.73 | Soluble | C |
| Comparative | | Cyclohexane | 3.44 | Insoluble | — |
| Example 1-1 | | | | | |
| Comparative | | n-hexane | 4.11 | Insoluble | — |
| Example 1-2 | | | | | |
| Comparative | | n-heptane | 4.66 | Insoluble | — |
| Example 1-3 | | | | | |

### Examples 2-1 to 2-11 and Comparative Examples 2-1 to 2-3

5.0 g of the additive solvent for solution formation or the comparative solvent shown in Table 2 was added to 1.0 g (slurry concentration: 9% by mass) of the liquid containing the white precipitate obtained in Hydrolysis Polycondensation Example 2. The solubility was evaluated by the same manner as in Example 1.

Various kinds of information are collectively shown in Table 2.

TABLE 2

| | | Additive solvent for | | | |
|---|---|---|---|---|---|
| | | solution formation (or | | | |
| | | comparative solvent) | | | |
| | | | 1- | | |
| | | | octanol/water | | |
| | Hydrolysis | | partition | Solubility | |
| | Polycondensation | | coefficient | | Ease of |
| | Example | Type | (log P_{ow}) | Solubility/Insolubility | Dissolution |
| Example 2-1 | 2 | Glycerin | −1.76 | Soluble | B |
| Example 2-2 | | Methanol | −0.82 | Soluble | A |
| Example 2-3 | | PGME | −0.49 | Soluble | A |
| Example 2-4 | | Ethanol | −0.32 | Soluble | A |
| Example 2-5 | | IPA | 0.05 | Soluble | A |
| Example 2-6 | | Cyclohexane | 0.08 | Soluble | A |
| Example 2-7 | | Methyl | 0.29 | Soluble | A |
| | | ethyl | | | |
| | | ketone | | | |
| Example 2-8 | | PGMEA | 1.20 | Soluble | A |
| Example 2-9 | | MIBC | 1.43 | Soluble | A |
| Example 2-10 | | n-butyl | 1.82 | Soluble | A |
| | | acetate | | | |
| Example 2-11 | | Toluene | 2.73 | Soluble | C |
| Comparative | | Cyclohexane | 3.44 | Insoluble | — |
| Example 2-1 | | | | | |
| Comparative | | n-hexane | 4.11 | Insoluble | — |
| Example 2-2 | | | | | |
| Comparative | | n-heptane | 4.66 | Insoluble | — |
| Example 2-3 | | | | | |

As shown in Tables 1 and 2, the polymer (which precipitated in the polymer solvent immediately after polymerization) having the constitutional unit represented by General Formula (1) and the constitutional unit represented by General Formula (1-A) was well dissolved in the solvent having a 1-octanol/water partition coefficient log P_{ow} of 3 or less. This result indicates that, the technique described in this specification makes it possible to provide a homogeneous resin composition while containing a polymer into which a metal element is introduced.

<Additional Evaluation: Preparation of Substrate with Multilayer Film and Sensitivity Evaluation by Electron Beam Irradiation>

Hereinafter, examples in which a substrate with a multilayer film is prepared using the resin composition described above, and the sensitivity to electron beam irradiation is evaluated will be described. In the examples, as the simulation test, a cured film (underlayer film) and a resist layer were formed on a substrate on which an organic layer was not formed in this order.

Hereinafter, unless otherwise specified, the film thickness was measured with an ellipsometer manufactured by HORIBA, Ltd.

### Example 3

PGMEA was added to the liquid containing the white precipitate obtained in Hydrolysis Polycondensation Example 1 to dissolve the white precipitate, thereby obtaining a homogeneous resin composition with a solid content concentration of 2% by mass.

The obtained resin composition was filtered through a filter having a pore size of 0.22 μm, and applied onto a silicon wafer having a diameter of 4 inches and a thickness of 525 μm, manufactured by SUMCO CORPORATION, by spin coating at a rotation speed of 3,000 rpm. Thereafter, the silicon wafer was placed on a hot plate and heated at 250° C. for 3 minutes. In this manner, a cured film 1 having a film thickness of 20 nm was formed on the silicon wafer.

### Example 4

PGMEA was added to the liquid containing the white precipitate obtained in Hydrolysis Polycondensation Example 2 to dissolve the white precipitate, thereby obtaining a homogeneous resin composition with a solid content concentration of 1% by mass.

The obtained resin composition was filtered through a filter having a pore size of 0.22 μm, and applied onto a silicon wafer having a diameter of 4 inches and a thickness of 525 μm, manufactured by SUMCO CORPORATION, by spin coating at a rotation speed of 500 rpm. Thereafter, the silicon wafer was placed on a hot plate and heated at 250° C. for 3 minutes. In this manner, a cured film 2 having a film thickness of 20 nm was formed on the silicon wafer.

### Comparative Example 4

A resin solution was obtained by performing hydrolysis and polycondensation in the same procedure as in Hydrolysis Polycondensation Example 1, except that Ph-Si, methyltriethoxysilane, and TEOS were used at a molar ratio of 5: 10: 85 (total: 16.0 mmol) instead of using Ph-Si, TEOS, and TEOG in Hydrolysis Polycondensation Example 1.

PGMEA was added to the resin solution to obtain a homogeneous resin composition having a solid content concentration of 1% by mass. The obtained resin composition was filtered through a filter having a pore size of 0.22 μm, and applied to a silicon wafer having a diameter of 4 inches and a thickness of 525 μm, manufactured by SUMCO Corporation, by spin coating at a rotation speed of 500 rpm. Thereafter, the silicon wafer was placed on a hot plate and heated at 250° C. for 3 minutes. In this manner, a comparative cured film 1 having a film thickness of 20 nm was obtained on the silicon wafer.

### [Preparation of Resist Layer]

A positive electron beam resist composition ZEP-520A, manufactured by Zeon Corporation, was filtered through a filter having a pore size of 0.22 μm, and the obtained solution was applied onto each of the cured films 1 and 2 and the comparative cured film 1 formed above by spin coating at a rotation speed of 2,000 rpm. Thereafter, the film was heated on a hot plate at 150° C. for 1 minute. In this manner, multilayer films 1 and 2 were formed by laminating a resist layer having a film thickness of 20 nm on each of the cured films 1 and 2 and the comparative cured film 1.

### [Sensitization Confirmation Test (Electron Beam Irradiation Test)]

Each of the resist layer surfaces of the multilayer films 1 to 2 and the comparative multilayer film 1 was irradiated with an electron beam using ELS-G100-SP (100 keV) manufactured by Elionix Inc. Specifically, the electron beam was applied while changing the irradiation position of the electron beam and changing the electron beam irradiation amount from 5 μC/cm² to 250 μC/cm² in increments of 5 μC/cm².

The multilayer films 1 and 2 and the comparative multilayer film 1 after the electron beam irradiation were immersed in butyl acetate for 30 seconds to be developed. The film thickness of the film after development was measured with DektaK-XT-A manufactured by Bruker Corporation, and the irradiation amount at which the film thickness of the resist layer was reduced to zero was defined as a required irradiation amount Eₜₕ. The smaller Eₜₕ is, the higher the sensitivity.

Various kinds of information are collectively shown in Table 3.

TABLE 3

| Multilayer film | | | Sensitization |
|---|---|---|---|
| | Cured film | | Confirmation Test |
| No. | (Underlayer film) | Resist layer | Eₜₕ [μC/cm²] |
| Multilayer film | Cured film 1 | ZEP-520A | 69.91 |
| 1 | (Containing | | |
| | sensitizing element) | | |
| Multilayer film | Cured film 2 | ZEP-520A | 52.91 |
| 2 | (Containing | | |
| | sensitizing element) | | |
| Comparative | Comparative cured | ZEP-520A | 76.58 |
| multilayer film | film 1 | | |
| 1 | (Not containing | | |
| | sensitizing element) | | |

As shown in Table 3, in the substrates 1 and 2 with a multilayer film containing the sensitizing element, Eₜₕ was smaller than in the substrate 1 with a comparative multilayer film not containing the sensitizing element. From this result, it is understood that, in the substrates 1 and 2 with a multilayer film containing the sensitizing element, a large amount of secondary electrons are generated in the underlayer film during the electron beam irradiation, and the secondary electrons flow into the resist layer, so that Eₜn is reduced.

Although the above description is an evaluation by electron beam irradiation, it has been reported that the sensitivity of the resist in the electron beam irradiation and the sensitivity of the resist in the EUV light irradiation are correlated with each other (for example, Radiation Chemistry, No. 107 (2019)). Therefore, it is considered that the sensitivity improving effect as described above can be obtained even in a case of exposure with EUV light.

### <Confirmation of Applicability to Electronic Device Production Step: Etching Evaluation and the Like>

Hereinafter, it is shown that the film formed of the above-described resin composition has appropriate dry etching resistance and can be used in the same electronic device production step as the composition for forming an underlayer film in the related art.

### [Formation of Organic Underlayer Film]

10 g of cresol novolac resin KA-1160 (manufactured by DIC Corporation), 2 g of a glycoluril curing agent NIKALAC MX279 (manufactured by NIPPON CARBIDE INDUSTRIES CO., INC.), 0.1 g of a paratoluenesulfonic acid pyridinium salt, and 190 g of cyclohexanone were mixed with each other to obtain a resin composition. The obtained resin composition was filtered through a filter having a pore size of 0.22 μm, and applied onto a silicon wafer having a diameter of 4 inches and a thickness of 525 μm, manufactured by SUMCO Corporation, by spin coating at a rotation speed of 1,000 rpm. Thereafter, the silicon wafer was placed on a hot plate and heated at 250° C. for 3 minutes. In this manner, an organic underlayer film 1 having a film thickness of 200 nm was obtained on the silicon wafer.

### [Formation of Multilayer Film 3]

PGMEA was added to the liquid containing the white precipitate obtained in Hydrolysis Polycondensation 2 and dissolved to obtain a homogeneous resin composition with a solid content concentration of 3% by mass. The obtained resin composition was filtered through a filter having a pore size of 0.22 μm, and applied onto the organic underlayer film 1 formed above by spin coating at a rotation speed of 1,400 rpm. Thereafter, the film was heated on a hot plate at 250° C. for 3 minutes. In this manner, a multilayer film 3 in which a resist underlayer film having a film thickness of 50 nm was laminated on the organic underlayer film 1 was formed.

### [Formation of Multilayer Film 4]

A positive tone electron beam resist composition ZEP-520A, manufactured by Zeon Corporation, was filtered through a filter having a pore size of 0.22 μm, and applied onto the multilayer film 3 formed above by spin coating at a rotation speed of 500 rpm. Thereafter, the film was heated on a hot plate at 150° C. for 1 minute. In this manner, a multilayer film 4 in which a resist layer having a film thickness of 50 nm was laminated on the multilayer film 3 was formed.

### [Electron Beam Irradiation]

The surface of the resist layer of the substrate on which the multilayer film 4 was formed was irradiated with an electron beam using ELS-7000EX (50 keV) manufactured by Elionix Ltd. while setting the exposure amount to 150 μC/cm², and the exposure line width to a line width of 100 μm and a space of 100 μm. Thereafter, the substrate with a multilayer film was immersed in butyl acetate for 30 seconds and developed. In this manner, a substrate with a multilayer film with a resist pattern was obtained.

### [Preparation of Substrate With Pattern: Pattern Transfer by Fluorine Etching]

The substrate with the multilayer film with the resist pattern was treated using an RIE-101iPH etching apparatus, manufactured by Samco Inc., under a pressure of 0.67 Pa, a CHF₃ gas, a flow rate of 40 sccm, an antenna power of 100 W, and a bias power of 25 W for 40 seconds to perform dry etching of the lower resist underlayer film. In this manner, the pattern of the resist layer was transferred to the resist underlayer film to obtain a substrate with a multilayer film with a resist underlayer film pattern.

[Preparation of Substrate with Pattern: Pattern Transfer by Oxygen Etching]

The substrate with the multilayer film with the resist underlayer film pattern was treated using an RIE-101iPH etching apparatus, manufactured by Samco Inc., under a pressure of 1 Pa, an O₂ gas, a flow rate of 20 sccm, an antenna power of 75 W, and a bias power of 100 W for 70 seconds to perform dry etching of the organic underlayer film. In this manner, the pattern of the resist underlayer film was transferred to the organic underlayer film to obtain a substrate with a multilayer film with an organic underlayer film pattern.

[Preparation of Substrate with Pattern: Pattern Transfer by Fluorine Etching]

The substrate with the multilayer film with the organic underlayer film pattern was treated using an RIE-101iPH etching apparatus, manufactured by Samco Inc., under a pressure of 0.67 Pa, a CHF₃ gas, a flow rate of 40 sccm, an antenna power of 100 W, and a bias power of 25 W for 80 seconds to perform dry etching of the silicon wafer. In this manner, the pattern of the organic underlayer film was transferred to the silicon wafer to obtain a substrate with a silicon pattern.

The substrate with a pattern was fractured and observed with a Helios G3CX focused ion beam scanning electron microscope, manufactured by Thermo Fisher Scientific Inc. As a result of the observation, it was confirmed that a pattern with a line width of 100 μm and a space of 100 μm was transferred onto the silicon substrate.

From this confirmation result, it was confirmed that the resin cured product containing the sensitizing element, such as the above-described resin composition, can also be used in a multilayer resist process, similar to resin compositions for forming an underlayer film in the related art.

This application claims priority based on Japanese Patent Application No. 2022-096018 filed on Jun. 14, 2022, the entire disclosure of which is incorporated herein.

### REFERENCE SIGNS LIST

100 substrate with multilayer film
101 base material
103 organic layer
105 underlayer film
107 resist layer
109 photomask
150 substrate with pattern
201 base material
203 photosensitive resin film
203a exposed portion
205 photomask
207 patterned film
211 patterned cured film

1. A resin composition comprising:
a polymer having a constitutional unit represented by General Formula (1), and a constitutional unit represented by General Formula (1-A); and
a solvent having a 1-octanol/water partition coefficient log P_{ow} of 3 or less, 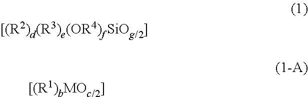
in General Formula (1),
in a case where a plurality of R²'s are present, R²'s are each independently an aryl group or an aralkyl group,
in a case where a plurality of R³'s are present, R³'s are each independently a hydrogen atom, a linear or branched aliphatic hydrocarbon group, or an aromatic hydrocarbon group,
in a case where a plurality of R⁴'s are present, R⁴'s are each independently a hydrogen atom or a linear or branched aliphatic hydrocarbon group,
d is a number of 1 or more and 3 or less, e is a number of 0 or more and 2 or less, f is a number of 0 or more and less than 3, g is a number of more than 0 and 3 or less, and d+e+f+g=4,
in General Formula (1-A),
M is at least one selected from the group consisting of Fe, Co, Ni, Cu, Zn, Ga, Ge, Mo, Pd, Ag, Sn, Cs, Ba, W, and Hf,
in a case where a plurality of R's are present, R¹'s are each independently a hydrogen atom, a hydroxy group, a halogen group, an alkoxy group, a linear or branched aliphatic hydrocarbon group, or an aromatic hydrocarbon group,
b is a number of 0 or more and less than 6, c is a number of more than 0 and 6 or less, and b+c=3 to 6.

2. A resin composition comprising:
a polysiloxane compound having a constitutional unit represented by General Formula (1);
a polymetalloxane compound having a constitutional unit represented by General Formula (1-A); and
a solvent having a 1-octanol/water partition coefficient log P_{ow} of 3 or less, 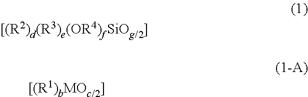
in General Formula (1),
in a case where a plurality of R²'s are present, R²'s are each independently an aryl group or an aralkyl group,
in a case where a plurality of R³'s are present, R³'s are each independently a hydrogen atom, a linear or branched aliphatic hydrocarbon group, or an aromatic hydrocarbon group,
in a case where a plurality of R⁴'s are present, R⁴'s are each independently a hydrogen atom or a linear or branched aliphatic hydrocarbon group,
d is a number of 1 or more and 3 or less, e is a number of 0 or more and 2 or less, f is a number of 0 or more and less than 3, g is a number of more than 0 and 3 or less, and d+e+f+g=4,
in General Formula (1-A),
M is at least one selected from the group consisting of Fe, Co, Ni, Cu, Zn, Ga, Ge, Mo, Pd, Ag, Sn, Cs, Ba, W, and Hf,
in a case where a plurality of R¹'s are present, R¹'s are each independently a hydrogen atom, a hydroxy group, a halogen group, an alkoxy group, a linear or branched aliphatic hydrocarbon group, or an aromatic hydrocarbon group,
b is a number of 0 or more and less than 6, c is a number of more than 0 and 6 or less, and b+c=3 to 6.

3. The resin composition according to claim 1,
wherein the solvent includes at least one selected from the group consisting of glycol ethers, alcohols, esters, and ketones.

4. The resin composition according to claim 1,
wherein the polymer further includes a constitutional unit represented by General Formula (2) and/or General Formula (3), 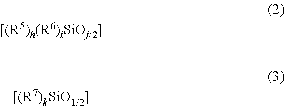
in General Formula (2),
in a case where a plurality of R⁵'s are present, R⁵'s are each independently a monovalent organic group having 1 or more and 30 or less carbon atoms and substituted with at least any substituent selected from the group consisting of an epoxy group, an oxetane group, an acryloyl group, a methacryloyl group, and a lactone group,
in a case where a plurality of R⁶'s are present, R⁶'s are each independently any group selected from the group consisting of a hydrogen atom, a halogen group, an alkyl group having 1 or more and 5 or less carbon atoms, a phenyl group, a hydroxy group, an alkoxy group having 1 or more and 3 or less carbon atoms, and a fluoroalkyl group having 1 or more and 10 or less carbon atoms,
h is a number of 1 or more and 3 or less, i is a number of 0 or more and less than 3, j is a number of more than 0 and 3 or less, and h+i+j=4,
in General Formula (3),
in a case where a plurality of R⁷'s are present, R⁷'s are each independently any group selected from the group consisting of a halogen group, an alkoxy group, and a hydroxy group,
k is a number of 0 or more and less than 4, 1 is a number of more than 0 and 4 or less, and k+1=4.

5. The resin composition according to claim 4,
wherein the monovalent organic group R⁵ is any of groups represented by General Formulae (2a), (2b), (2c), (3a), and (4a), 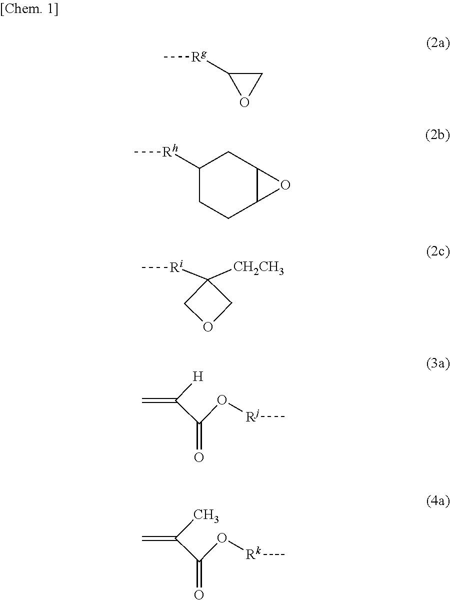
in General Formulae (2a), (2b), and (2c),
R^{g}, R^{h}, and Rⁱ each independently represent a divalent linking group, and
broken lines represent bonds,
in General Formulae (3a) and (4a),
R^{j} and R^{k} each independently represent a divalent linking group, and
broken lines represent bonds.

6. The resin composition according to claim 2,
wherein at least one of the polysiloxane compound and the polymetalloxane compound further includes a constitutional unit represented by General Formula (2) and/or General Formula (3), 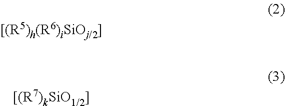
in General Formula (2),
in a case where a plurality of R⁵'s are present, R⁵'s are each independently a monovalent organic group having 1 or more and 30 or less carbon atoms and substituted with at least any substituent selected from the group consisting of an epoxy group, an oxetane group, an acryloyl group, a methacryloyl group, and a lactone group,
in a case where a plurality of R⁶'s are present, R⁶'s are each independently any group selected from the group consisting of a hydrogen atom, a halogen group, an alkyl group having 1 or more and 5 or less carbon atoms, a phenyl group, a hydroxy group, an alkoxy group having 1 or more and 3 or less carbon atoms, and a fluoroalkyl group having 1 or more and 10 or less carbon atoms,
h is a number of 1 or more and 3 or less, i is a number of 0 or more and less than 3, j is a number of more than 0 and 3 or less, and h+i+j=4,
in General Formula (3),
in a case where a plurality of R⁷'s are present, R⁷'s are each independently any group selected from the group consisting of a halogen group, an alkoxy group, and a hydroxy group,
k is a number of 0 or more and less than 4, 1 is a number of more than 0 and 4 or less, and k+1=4.

7. The resin composition according to claim 6,
wherein the monovalent organic group R⁵ is any of groups represented by General Formulae (2a), (2b), (2c), (3a), and (4a), 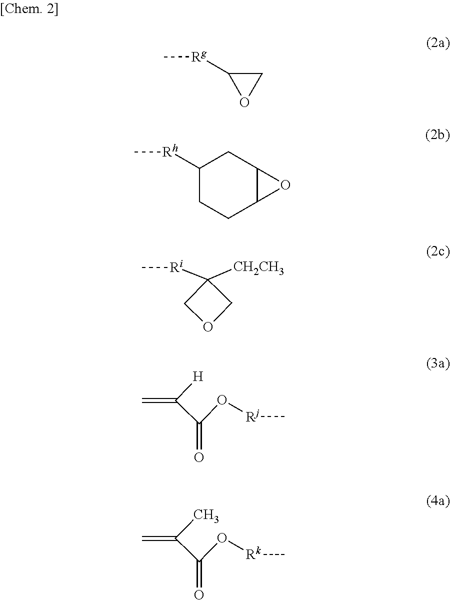
in General Formulae (2a), (2b), and (2c),
R⁹, R^{h}, and Rⁱ each independently represent a divalent linking group, and
broken lines represent bonds,
in General Formulae (3a) and (4a),
R^{j} and R^{k} each independently represent a divalent linking group, and
broken lines represent bonds.

8. The resin composition according to claim 1,
wherein in General Formula (1-A), M is at least one selected from the group consisting of Ge, Mo, and W.

9. The resin composition according to claim 2,
wherein in General Formula (1-A), M is at least one selected from the group consisting of Ge, Mo, and W.

10. The resin composition according to claim 1,
wherein a non-volatile component concentration is 1% to 50% by mass.

11. The resin composition according to claim 1,
wherein the number of particles having a particle diameter of more than 0.2 μm in particle measurement with a light scattering type liquid-borne particle detector is 100 or less per 1 mL.

12. A method for producing a cured film, comprising:
a resin film forming step of applying the resin composition according to claim 1 onto a substrate to form a resin film; and
a heating step of heating the resin film at a temperature of 80° C. or higher and 350° C. or lower.

13. A substrate with a multilayer film, comprising:
a substrate;
an organic layer that is provided on one surface of the substrate;
a resist underlayer film that is a cured film of the resin composition according to claim 1 and is provided on a surface of the organic layer opposite to the substrate; and
a resist layer that is provided on a surface of the resist underlayer film opposite to the organic layer.

14. A method for producing a substrate with a pattern, comprising:
a first step of exposing the resist layer of the substrate with a multilayer film according to claim 13 through a photomask, and then developing the exposed resist layer with a developer to obtain a pattern;
a second step of dry-etching the resist underlayer film through the pattern of the developed resist layer to obtain a pattern of the underlayer film;
a third step of dry-etching the organic layer through the pattern of the underlayer film to obtain a pattern of the organic layer; and
a fourth step of dry-etching the substrate through the pattern of the organic layer to obtain a pattern of the substrate.

15. The method for producing a substrate with a pattern according to claim 14,
wherein, in the second step, the underlayer film is dry-etched with a fluorine-based gas,
in the third step, the organic layer is dry-etched with an oxygen-based gas, and
in the fourth step, the substrate is dry-etched with a fluorine-based gas or a chlorine-based gas.

16. The method for producing a substrate with a pattern according to claim 14,
wherein a wavelength of a light beam used in the exposure is 1 nm or more and 600 nm or less.

17. The method for producing a substrate with a pattern according to claim 14,
wherein a wavelength of a light beam used in the exposure is 6 nm or more and 27 nm or less.

18. The method for producing a substrate with a pattern according to claim 14,
wherein a light beam used in the exposure is EUV light.

19. The method for producing a substrate with a pattern according to claim 14,
wherein the developer is an organic solvent-based developer.

20. The resin composition according to claim 1, further comprising:
a photoinduced compound,
wherein the resin composition has photosensitivity.

21. The resin composition according to claim 20,
wherein the photoinduced compound is at least one selected from the group consisting of naphthoquinone diazide, a photoacid generator, a photobase generator, and a photoradical generator.

22. A method for producing a patterned cured film, comprising:
a photosensitive resin film forming step of applying the resin composition according to claim 20 onto a substrate to form a photosensitive resin film;
an exposing step of exposing the photosensitive resin film through a photomask;
a developing step of developing the exposed photosensitive resin film to form a patterned film; and
a curing step of curing the patterned film by heating the patterned film to form a patterned cured film.

23. The method for producing a patterned cured film according to claim 22,
wherein in the exposing step, the photosensitive resin film is irradiated with a light beam having a wavelength of 1 nm or more and 600 nm or less through the photomask.

24. A method for producing the resin composition according to claim 1, comprising:
a solution forming step of mixing a polymer obtained by conducting hydrolysis and polycondensation of a silicon compound represented by General Formula (1y) and a metal compound represented by General Formula (1-2), and the solvent having a 1-octanol/water partition coefficient of 3 or less to form a solution, 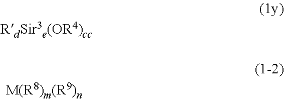
in General Formula (1y),
in a case where a plurality of R's are present, R's are each independently an aryl group or an aralkyl group,
R³ has the same definition as in General Formula (1)
R⁴ has the same definition as in General Formula (1),
d is a number of 1 or more and 3 or less, e is a number of 0 or more and 2 or less, cc is a number of 1 or more and less than 4, and d+e+cc=4,
in General Formula (1-2),
M has the same definition as in General Formula (1-A),
in a case where a plurality of R⁸'s are present, R⁸'s are each independently a hydrogen atom, a hydroxy group, a linear or branched aliphatic hydrocarbon group, or an aromatic hydrocarbon group,
in a case where a plurality of R⁹'s are present, R⁹'s are each independently an alkoxy group or halogen,
m is a number of 0 or more and 3 or less, n is a number of 1 or more and 4 or less, and m+n=3 or 4.

25. The method for producing the resin composition according to claim 24,
wherein a chelating agent is used in obtaining the polymer.

26. The method for producing the resin composition according to claim 24,
wherein after the solution forming step, at least one operation selected from the group consisting of dilution with a solvent, concentration, extraction, washing with water, ion exchange resin purification, and filtration is further performed.
